(19) United States
(12) Patent Application Publication
(10) Pub. No.: US 2026/0268946 A1
(43) Pub. Date: Sep. 10, 2026

(54) SEMICONDUCTOR DEVICE INCLUDING MEMORY CELLS AND GLOBAL BIT LINES

(71) Applicant: SAMSUNG ELECTRONICS CO., LTD., Suwon-si (KR)

(72) Inventors: Yujin Kim, Suwon-si (KR); Jinwoo Han, Suwon-si (KR); Juhyun Kim, Suwon-si (KR); Hyeoncheol Kim, Suwon-si (KR)

(73) Assignee: SAMSUNG ELECTRONICS CO., LTD., Suwon-si (KR)

(21) Appl. No.: 19/553,935

(22) Filed: Mar. 2, 2026

(30) Foreign Application Priority Data
Mar. 5, 2025 (KR) 10-2025-0028100

(51) Int. Cl. G11C 5/06; G11C 11/4091; G11C 11/4097; H10B 12/00

(52) U.S. Cl. CPC G11C 5/063; G11C 11/4091; G11C 11/4097; H10B 12/482; H10B 12/485

(57) ABSTRACT

A semiconductor device may include: memory cells disposed three-dimensionally in a vertical direction, a first direction, and a second direction perpendicular to each other; local bit lines disposed at a same level in the vertical direction and connected to the memory cells; and global bit lines disposed at a higher level in the vertical direction than the local bit lines and connected to the local bit lines, wherein the global bit lines include: first global bit lines connected to N first local bit lines among the local bit lines, N may be a natural number equal to or greater than 2; and second global bit lines connected to N second local bit lines among the local bit lines. Each of the memory cells may include: a cell transistor including a cell gate electrode extending in the second direction; and a data storage structure.

### CROSS-REFERENCE TO RELATED APPLICATION

This application claims benefit of priority to Korean Patent Application No. 10-2025-0028100 filed on Mar. 5, 2025 in the Korean Intellectual Property Office, the disclosure of which is incorporated herein by reference in its entirety.

### BACKGROUND

Example embodiments of the present disclosure relate to a semiconductor device including memory cells and global bit lines.

Research has been conducted to reduce the sizes of elements included in a semiconductor device and to improve performance thereof. For example, in a DRAM, research to reliably and stably form elements having reduced sizes has been conducted, but as the sizes of elements are reduced, dispersion properties of a semiconductor device may be deteriorated.

### SUMMARY

One or more embodiments of the present disclosure is to provide a semiconductor device having increased integration density.

One or more embodiments of the present disclosure is to provide a semiconductor device having improved performance.

One or more embodiments of the present disclosure is to provide a method of manufacturing the semiconductor device.

According to an aspect of the disclosure, a semiconductor device may include: memory cells disposed three-dimensionally in a vertical direction, a first direction, and a second direction perpendicular to each other; local bit lines disposed at a same level in the vertical direction and connected to the memory cells; and global bit lines disposed at a higher level in the vertical direction than the local bit lines and connected to the local bit lines, wherein the global bit lines include: first global bit lines connected to N first local bit lines among the local bit lines, N may be a natural number equal to or greater than 2; and second global bit lines connected to N second local bit lines among the local bit lines. Each of the memory cells may include: a cell transistor including a cell gate electrode extending in the second direction; and a data storage structure. Each of the first global bit lines may include a first bit line portion. Each of the second global bit lines may include a second bit line portion disposed at a higher level in the vertical direction than the first bit line portions of the first global bit lines. Three local bit lines, sequentially disposed in the first direction among the local bit lines, may be respectively connected to three global bit lines that are spaced apart among the global bit lines.

According to an aspect of the disclosure, a semiconductor device may include: memory cells disposed three-dimensionally in a vertical direction, a first direction, and a second direction perpendicular to each other; local bit lines connected to the memory cells and disposed at a same level in the vertical direction; global bit lines disposed at a higher level in the vertical direction than the local bit lines and connected to the local bit lines; bit line sense amplifiers disposed at a higher level in the vertical direction than the global bit lines; and global bit line select circuits connected to the bit line sense amplifiers and the global bit lines. Each of the global bit lines may be connected to N local bit lines among the local bit lines, N may be a natural number equal to or greater than 2, a first global bit line among the global bit lines may include a first bit line portion, a second global bit line among the global bit lines may include a second bit line portion disposed at a higher level in the vertical direction than the first bit line portion, the global bit line select circuits may include a first global bit line select circuit connected to a first bit line sense amplifier among the bit line sense amplifiers, and the global bit lines may include M global bit lines connected to the first global bit line select circuit, M may be a natural number equal to or greater than 4.

According to an aspect of the disclosure, a semiconductor device may include: a first structure; and a second structure disposed on the first structure and bonded to the first structure. The first structure may include: memory cells disposed three-dimensionally in a vertical direction, a first direction, and a second direction perpendicular to each other; local bit lines connected to the memory cells and disposed at a same level in the vertical direction; and global bit lines disposed at a higher level in the vertical direction than the local bit lines and connected to the local bit lines. The global bit lines may include: first global bit lines connected to N first local bit lines among the local bit lines, wherein an N is a natural number equal to or greater than 2; and second global bit lines connected to N second local bit lines among the local bit lines. Each of the memory cells may include: a cell transistor including a cell gate electrode extending in the second direction; and a data storage structure. Each of the first global bit lines may include a first bit line portion, each of the second global bit lines may include a first bit line portion disposed at a higher level in the vertical direction than the first bit line portions of the first global bit lines, and three local bit lines, disposed in the first direction among the local bit lines, may be respectively connected to three global bit lines that are spaced apart among the global bit lines.

### BRIEF DESCRIPTION OF THE DRAWINGS

The above and other aspects, features, and advantages of the present disclosure will be more clearly understood from the following detailed description, taken in combination with the accompanying drawings, in which:

FIG. 1 is a diagram illustrating a semiconductor device according to one or more embodiments of the present disclosure;

FIG. 2A is a diagram illustrating a semiconductor device according to one or more embodiments of the present disclosure;

FIG. 2B is a diagram illustrating a semiconductor device according to one or more embodiments of the present disclosure;

FIG. 3 is a diagram illustrating a semiconductor device including an example circuit according to one or more embodiments of the present disclosure;

FIG. 4A is a diagram illustrating a semiconductor device according to one or more embodiments of the present disclosure;

FIG. 4B is a diagram illustrating a semiconductor device according to one or more embodiments of the present disclosure;

FIG. 5A is a diagram illustrating a semiconductor device according to one or more embodiments of the present disclosure;

FIG. 5B is a diagram illustrating a semiconductor device according to one or more embodiments of the present disclosure;

FIG. 6A is a diagram illustrating a semiconductor device according to one or more embodiments of the present disclosure;

FIG. 6B is a diagram illustrating a semiconductor device according to one or more embodiments of the present disclosure;

FIG. 7A is a diagram illustrating a semiconductor device according to one or more embodiments of the present disclosure;

FIG. 7B is a diagram illustrating a semiconductor device according to one or more embodiments of the present disclosure;

FIG. 8A is a diagram illustrating a semiconductor device according to one or more embodiments of the present disclosure;

FIG. 8B is a diagram illustrating a semiconductor device according to one or more embodiments of the present disclosure;

FIG. 9A is a diagram illustrating a semiconductor device according to one or more embodiments of the present disclosure;

FIG. 9B is a diagram illustrating a semiconductor device according to one or more embodiments of the present disclosure;

FIG. 10A is a diagram illustrating a semiconductor device according to one or more embodiments of the present disclosure;

FIG. 10B is a diagram illustrating a semiconductor device according to one or more embodiments of the present disclosure;

FIG. 11A is a diagram illustrating a semiconductor device according to one or more embodiments of the present disclosure;

FIG. 11B is a diagram illustrating a semiconductor device according to one or more embodiments of the present disclosure;

FIG. 12 is a diagram illustrating an example of a semiconductor device according to one or more embodiments of the present disclosure;

FIG. 13A is a diagram illustrating an example of a semiconductor device according to one or more embodiments of the present disclosure;

FIG. 13B is a diagram illustrating an example of a semiconductor device according to one or more embodiments of the present disclosure;

FIG. 14 is a diagram illustrating an example of a semiconductor device according to one or more embodiments of the present disclosure;

FIG. 15 is a diagram illustrating an example of a semiconductor device according to one or more embodiments of the present disclosure;

FIG. 16 is a diagram illustrating an example of a semiconductor device according to one or more embodiments of the present disclosure;

FIG. 17 is a diagram illustrating an example of a semiconductor device according to one or more embodiments of the present disclosure;

FIG. 18A is a diagram illustrating an example of a semiconductor device according to one or more embodiments of the present disclosure;

FIG. 18B is a diagram illustrating an example of a semiconductor device according to one or more embodiments of the present disclosure;

FIG. 19A is a diagram illustrating an example of a semiconductor device according to one or more embodiments of the present disclosure;

FIG. 19B is a diagram illustrating an example of a semiconductor device according to one or more embodiments of the present disclosure;

FIG. 20A is a diagram illustrating an example of a semiconductor device according to one or more embodiments of the present disclosure;

FIG. 20B is a diagram illustrating an example of a semiconductor device according to one or more embodiments of the present disclosure;

FIG. 21 is a diagram illustrating an example of a semiconductor device according to one or more embodiments of the present disclosure;

FIG. 22 is a diagram illustrating an example of a semiconductor device according to one or more embodiments of the present disclosure;

FIG. 23 is a diagram illustrating an example of a method of manufacturing a semiconductor device according to one or more embodiments of the present disclosure;

FIG. 24 is a diagram illustrating an example of a method of manufacturing a semiconductor device according to one or more embodiments of the present disclosure;

FIG. 25 is a diagram illustrating an example of a method of manufacturing a semiconductor device according to one or more embodiments of the present disclosure;

FIG. 26 is a diagram illustrating an example of a method of manufacturing a semiconductor device according to one or more embodiments of the present disclosure;

FIG. 27 is a diagram illustrating an example of a method of manufacturing a semiconductor device according to one or more embodiments of the present disclosure; and

FIG. 28 is a diagram illustrating an example of a method of manufacturing a semiconductor device according to one or more embodiments of the present disclosure.

### DETAILED DESCRIPTION

Hereinafter, embodiments of the present disclosure will be described as follows with reference to the accompanying drawings.

Hereinafter, the terms such as “higher,” “lower,” “upper portion,” “intermediate portion” and “lower portion” may be replaced with other terms, such as “first,” “second” and “third,” to describe elements of the example embodiments. The terms such as “first,” “second” and “third” may be used to describe various elements, but the elements are not limited by the terms, and a “first element” may be denoted a “second element.” In the example embodiments, the terms such as “lower portion,” “upper portion,” “upper end” and “lower end” may be described based on the drawings.

Herein, when describing “levels” of components, it may refer to levels having relative heights in a vertical direction. Moreover, when components are described as “connected,” they may be electrically, physically, and/or configured to be electrically connected.

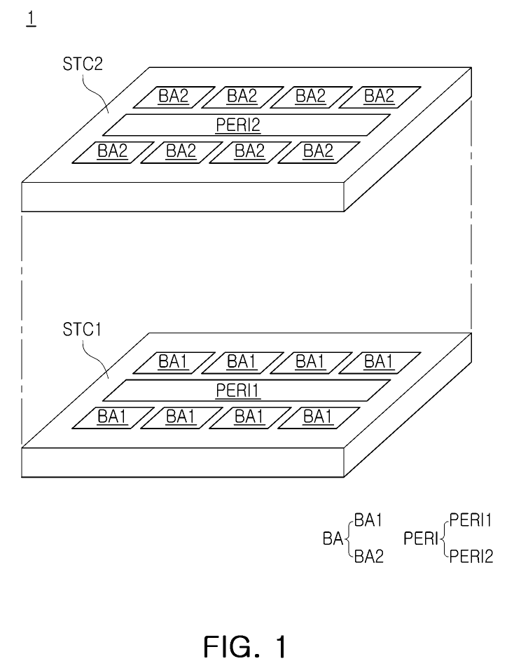

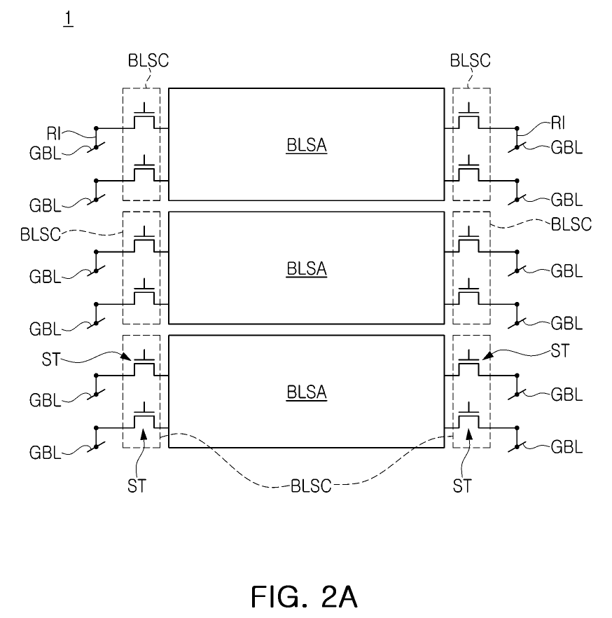

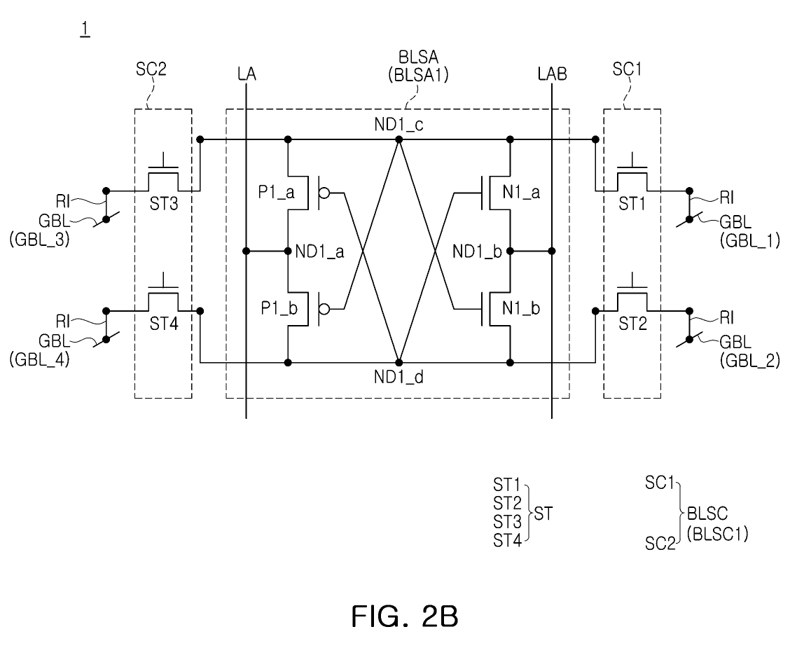

First, a semiconductor device according to one or more embodiments will be described with reference to FIGS. 1, 2A, and 2B. In FIGS. 1, 2A, and 2B, FIG. 1 is a perspective diagram illustrating a semiconductor device according to one or more embodiments, FIG. 2A is a diagram illustrating a semiconductor device according to one or more embodiments, and FIG. 2B is a diagram including an example circuit of a semiconductor device according to one or more embodiments. Here, while describing a semiconductor device according to one or more embodiments with reference to FIGS. 1, 2A, and 2B, other diagrams may be cited and described.

Referring to FIGS. 1, 2A, and 2B, a semiconductor device 1 according to one or more embodiments may include a first structure STC1 and a second structure STC2 on the first structure STC1. The first structure STC1 and the second structure STC2 may be a structure bonded to each other by a wafer bonding process

In an example, the first structure STC1 and the second structure STC2 may be formed by bonding an insulating layer of the first structure STC1 and an insulating layer of the second structure STC2 to each other.

In an example, the first structure STC1 and the second structure STC2 may be formed by bonding an insulating layer of the first structure STC1 and an insulating layer of the second structure STC2 to each other, and bonding a metal layer (e.g., copper layer) of the first structure STC1 and a metal layer (e.g., copper layer) of the second structure STC2 to each other.

The semiconductor device 1 may include a plurality of banks BA and an external peripheral region PERI. The external peripheral region PERI may include a first peripheral region PERI1 in the first structure STC1, and a second peripheral region PERI2 in the second structure STC2. The external peripheral region PERI may be a peripheral circuit region in which peripheral circuits for input and output of data or commands, or input of power/ground, are disposed.

Each of the plurality of banks BA may include a first bank region BA1 in the first structure STC1 and a second bank region BA2 in the second structure STC2.

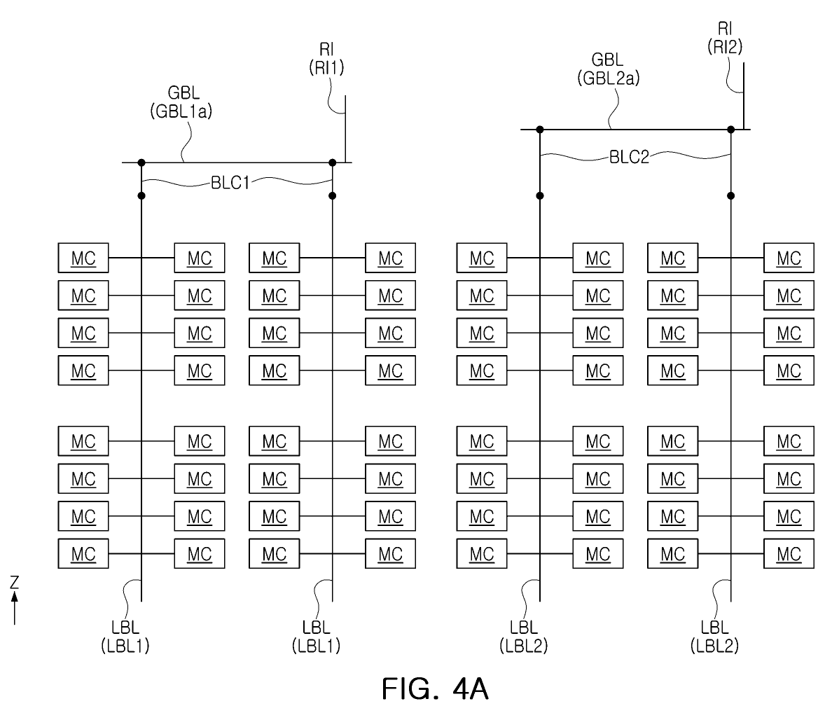

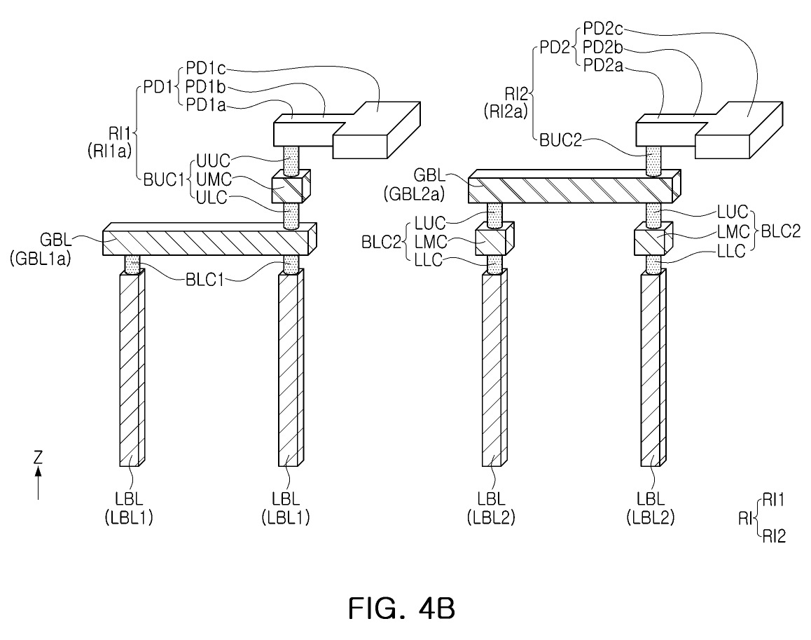

The first bank region BA1 of the first structure STC1 may include memory cells arranged three-dimensionally (e.g., MC in FIG. 4A), local bit lines (e.g., LBL in FIG. 4A) connected to the memory cells (e.g., MC in FIG. 4A), and global bit lines GBL connected to the local bit lines (e.g., LBL in FIG. 4A).

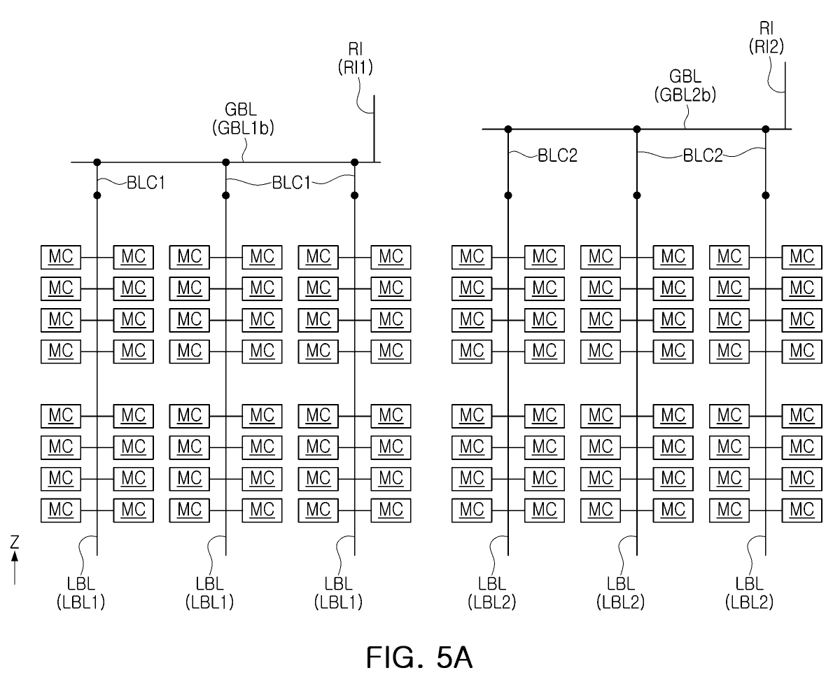

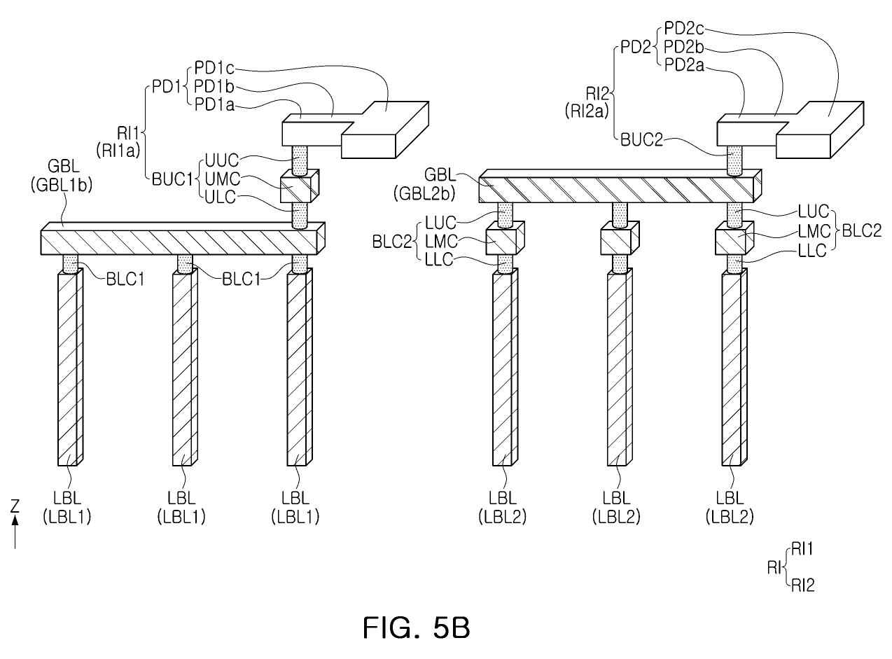

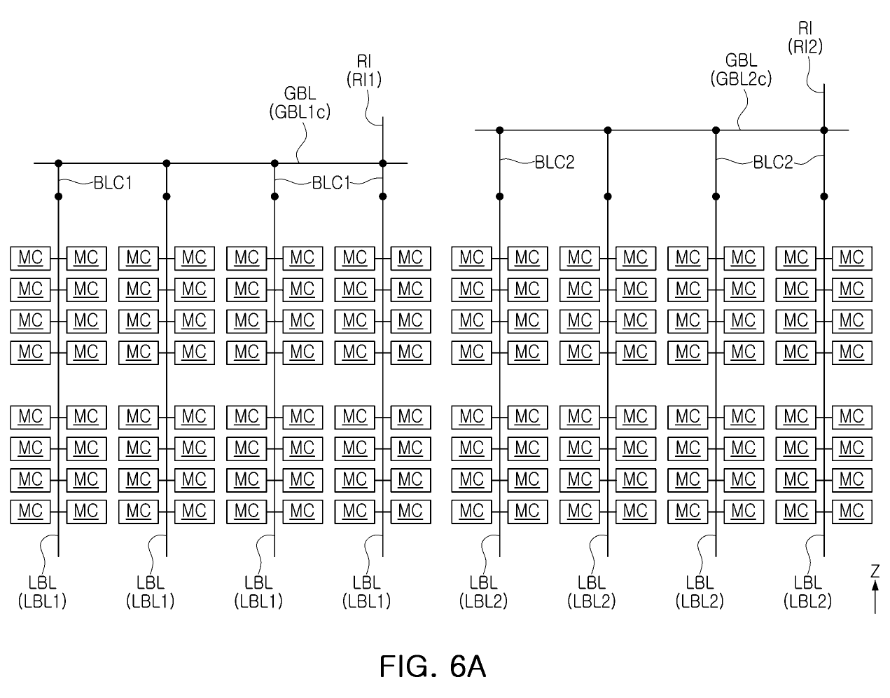

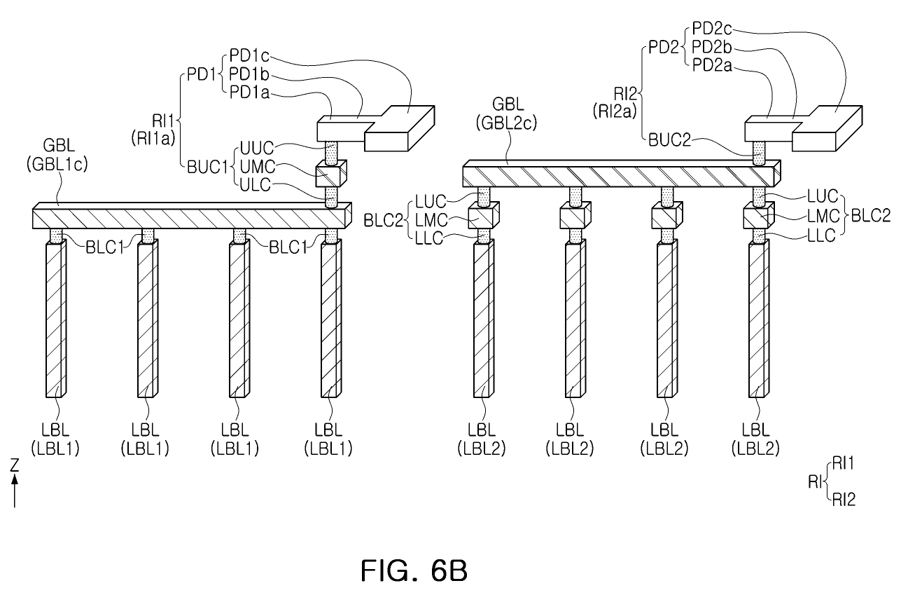

Each of the global bit lines GBL may be connected to an N number of local bit lines among the local bit lines (e.g., LBL in FIG. 4A). The “N” may be a natural number equal to or greater than 2. For example, each of the global bit lines GBL may be connected to two local bit lines (LBL in FIGS. 4A and 4B), three local bit lines (LBL in FIGS. 5A and 5B), or four local bit lines (LBL in FIGS. 6A and 6B), but one or more embodiments thereof is not limited thereto. For example, each of the global bit lines GBL may be connected to five or more local bit lines.

The second bank region BA2 of the second structure STC2 may include bit line sense amplifiers BLSA and bit line select circuits BLSC (which may also be referred to as a global bit bine select circuits) connected to the bit line sense amplifiers BLSA.

The first and second structures STC1 and STC2 may further include routing interconnection structures RI configured to electrically connect the bit line select circuits BLSC to the global bit lines GBL.

The bit line sense amplifiers BLSA may be connected to the global bit lines GBL through the routing interconnection structures RI. The routing interconnection structures RI may be configured to electrically connect the global bit lines GBL to the bit line sense amplifiers BLSA.

Each of the bit line sense amplifiers BLSA may be electrically connected to a pair of global bit lines selected by the bit line select circuit BLSC among the global bit lines GBL connected to the bit line sense amplifier BLSA depending on operation of the corresponding bit line select circuit BLSC among the bit line select circuits BLSC, and may not be electrically connected to a pair of global bit lines not selected by the bit line select circuit BLSC.

Each of the bit line sense amplifiers BLSA may be connected to M global bit lines GBL. In an example, “M” may be a natural number of 4 or more.

Each of the bit line sense amplifiers BLSA may include a plurality of sense amplifier transistors P1_a, P1_b, N1_a, and N1_b. The sense amplifier transistors P1_a, P1_b, N1_a, and N1_b may include a first PMOS transistor P1_a and a second PMOS transistor P1_b, and a first NMOS transistor N1_a and a second NMOS transistor N1_b.

Each of the bit line select circuits BLSC may include select transistors ST.

Each of the bit line select circuits BLSC may include a first select circuit SC1 and a second select circuit SC2. In each of the bit line select circuits BLSC, the first select circuit SC1 may include a first select transistor ST1 connected to a first global bit line GBL_1 among the global bit lines GBL and a second select transistor ST2 connected to a second global bit line GBL_2 among the global bit lines GBL.

In each of the bit line select circuits BLSC, the second select circuit SC2 may include a third select transistor ST3 connected to a third global bit line GBL_3 among the global bit lines GBL and a fourth select transistor ST4 connected to a fourth global bit line GBL_4 among the global bit lines GBL.

Hereinafter, the first bit line sense amplifier BLSA1 and the first bit line select circuit BLSC1, connected to each other, among the bit line sense amplifiers BLSA and the bit line select circuits BLSC, will be described.

The first PMOS transistor P1_a and the second PMOS transistor P1_b may be referred to as a PMOS transistor pair, and the first NMOS transistor N1_a and the second NMOS transistor N1_b may be referred to as an NMOS transistor pair.

The source of the first PMOS transistor P1_a and the source of the second PMOS transistor P1_b may be connected to a first control line LA through the first node ND1_a. A source of the first NMOS transistor N1_a and a source of the second NMOS transistor N1_b may be connected to a second control line LAB through the second node ND1_b. The first node ND1_a and the second node ND1_b may be referred to as a first source node and a second source node, respectively.

According to the operation of the first bit line select circuit BLSC1, a drain of the first PMOS transistor P1_a and a drain of the first NMOS transistor N1_a may be connected to the first global bit line GBL_1 or the third global bit line GBL_3 through the first drain node ND1_c.

According to operation of the first bit line select circuit BLSC1, a drain of the second PMOS transistor P1_b and a drain of the second NMOS transistor N1_b may be connected to the second global bit line GBL_2 or the fourth global bit line GBL_4, which may be a complementary bit line, among the global bit lines GBL through the second drain node ND1_d.

When the third select transistor ST3 and the fourth select transistor ST4 of the second select circuit SC2 operates in a turned-off state and the first select transistor ST1 and the second select transistor ST2 of the first select circuit SC1 operates in a turned-on state, the first and second global bit lines GBL_1 and GBL_2 may be a pair of global bit lines selected by the first bit line select circuit BLSC1 and electrically connected to the first bit line sense amplifier BLSA1, and the third and fourth global bit lines GBL_3 and GBL_4 may be a pair of global bit lines unselected by the first bit line select circuit BLSC1 and electrically isolated from the first bit line sense amplifier BLSA1. For example, when the third select transistor ST3 and the fourth select transistor ST4 of the second select circuit SC2 operate in a turned-off state and the first select transistor ST1 and the second select transistor ST2 of the first select circuit SC1 operate in a turned-on state, a drain of the first PMOS transistor P1_a and a drain of the first NMOS transistor N1_a may be connected to the first global bit line GBL_1 through the first drain node ND1_c, and a drain of the second PMOS transistor P1_b and a drain of the second NMOS transistor N1_b may be connected to the second global bit line GBL_2, which may be a complementary bit line, through the second drain node ND1_d.

When the third select transistor ST3 and the fourth select transistor ST4 of the second select circuit SC2 operate in a turned-on state and the first select transistor ST1 and the second select transistor ST2 of the first select circuit SC1 operate in a turned-off state, the first and second global bit lines GBL_1 and GBL_2 may be a pair of global bit lines not selected by the first bit line select circuit BLSC1 and electrically isolated from the first bit line sense amplifier BLSA1, and the third and fourth global bit lines GBL_3 and GBL_4 may be a pair of global bit lines selected by the first bit line select circuit BLSC1 and electrically connected to the first bit line sense amplifier BLSA1. For example, when the third select transistor ST3 and the fourth select transistor ST4 of the second select circuit SC2 operate in a turned-on state and the first select transistor ST1 and the second select transistor ST2 of the first select circuit SC1 operate in a turned-off state, a drain of the first PMOS transistor P1_a and a drain of the first NMOS transistor N1_a may be connected to the third global bit line GBL_3 through the first drain node ND1_c, and a drain of the second PMOS transistor P1_b and a drain of the second NMOS transistor N1_b may be connected to the fourth global bit line GBL_4, which may be a complementary bit line, through the second drain node ND1_d.

When the first bit line sense amplifier BLSA1 is electrically connected to the first and second global bit lines GBL_1 and GBL_2 by the first bit line select circuit BLSC1, and is not electrically connected to the third and fourth global bit lines GBL_3 and GBL_4 by the first bit line select circuit BLSC1, the first bit line sense amplifier BLSA1 may sense a voltage change of the first global bit line GBL_1 and may amplify the voltage change.

When the first bit line sense amplifier BLSA1 is not electrically connected to the first and second global bit lines GBL_1 and GBL_2 by the first bit line select circuit BLSC1, and is electrically connected to the third and fourth global bit lines GBL_3 and GBL_4 by the first bit line select circuit BLSC1, the first bit line sense amplifier BLSA1 may sense a voltage change of the third global bit line GBL_3 and may amplify the voltage change.

When the first bit line sense amplifier BLSA1 performs sensing and amplification operations, an internal power supply voltage may be applied to the first node ND1_a through the first control line LA, and the second node ND1_b may be connected to a ground terminal through the second control line LAB. The first bit line sense amplifier BLSA1 may include a PMOS transistor pair and an NMOS transistor pair, and may be implemented as a circuit element cross-coupled between the transistors, but one or more embodiments thereof is not limited thereto. For example, a circuit of the first bit line sense amplifier BLSA1 may be implemented as various circuit elements.

As described above, the first bit line sense amplifier BLSA1 may not be connected to the third and fourth global bit lines GBL_3 and GBL_4 when connected to the first and second global bit lines GBL_1 and GBL_2, and may be connected to the third and fourth global bit lines GBL_3 and GBL_4 when not connected to the first and second global bit lines GBL_1 and GBL_2, depending on operation of the first bit line select circuit BLSC1. Accordingly, the area occupied by the bit line sense amplifiers BLSA may be reduced, such that integration density of the semiconductor device 1 may be increased.

In one or more embodiments, the first and second select transistors ST1 and ST2 may be disposed on a first side of the first bit line sense amplifier BLSA1, and the third and fourth select transistors ST3 and ST4 may be disposed on a second side of the first bit line sense amplifier BLSA1 opposing the first side of the first bit line sense amplifier BLSA1.

In one or more embodiments, the first select circuit SC1 may include the first and second select transistors ST1 and ST2, and the second select circuit SC2 may include the third and fourth select transistors ST3 and ST4. Accordingly, the first select circuit SC1 may be disposed on a first side of the first bit line sense amplifier BLSA1, and the second select circuit SC2 may be disposed on a second side of the first bit line sense amplifier BLSA1 opposing the first side of the first bit line sense amplifier BLSA1.

Hereinafter, example embodiments of the semiconductor device 1 will be described. The various example embodiments described below and the aforementioned example embodiments may be combined and may form one or more embodiments. Hereinafter, elements described above may be directly cited without a detailed description, or the description may not be provided. Also, elements described below which may be modified or replaced may be described with reference to the diagrams, or elements which may be modified, replaced, or added may be combined with each other or with the elements described above and may form a semiconductor device according to the example embodiment. Also, when the elements described above include a plurality of elements, the example in which the number of elements is one will be described below.

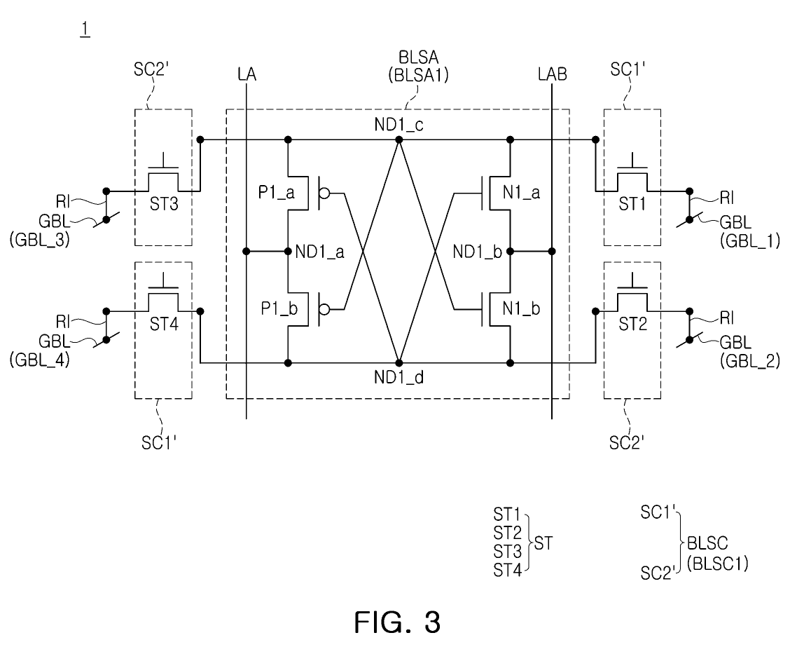

Referring to FIG. 3, one or more embodiments of the first select circuit SC1 and the second select circuit SC2 will be described. FIG. 3 is a circuit diagram illustrating one or more embodiments of the first select circuit SC1 and the second select circuit SC2 in the first bit line select circuit BLSC1 in FIG. 2B.

In one or more embodiments, referring to FIG. 3, the first select circuit SC1 illustrated in FIG. 2B may be replaced with a first select circuit SC1’ including the first select transistor ST1 and the fourth select transistor ST4, and the second select circuit SC2 illustrated in FIG. 2B may be replaced with a second select circuit SC2’ including the second select transistor and the third select transistor ST3.

The first select circuit SC1’ may include the first select transistor ST1 and the fourth select transistor ST4 disposed on both sides of the first bit line sense amplifier BLSA1. The second select circuit SC2 may include the third select transistor ST3 and the second select transistor ST2 disposed on both sides of the first bit line sense amplifier BLSA1.

When the first bit line sense amplifier BLSA1 is electrically connected to the first and fourth global bit lines GBL_1 and GBL_4 by the first bit line select circuit BLSC1, and is not electrically connected to the second and third global bit lines GBL_2 and GBL_3 by the first bit line select circuit BLSC1, the first bit line sense amplifier BLSA1 may sense a voltage change of the first global bit line GBL_b and amplify the voltage change.

When the first bit line sense amplifier BLSA1 is not electrically connected to the first and fourth global bit lines GBL_1 and GBL_4 by the first bit line select circuit BLSC1, and is electrically connected to the second and third global bit lines GBL_2 and GBL_3 by the first bit line select circuit BLSC1, the first bit line sense amplifier BLSA1 may sense a voltage change of the third global bit line GBL_3 and amplify the voltage change.

One or more embodiments in which each of the global bit lines GBL described above is connected to two local bit lines LBL will be described with reference to FIGS. 4A and 4B. FIG. 4A is a diagram illustrating a semiconductor device according to one or more embodiments, and FIG. 4B is a perspective diagram illustrating a semiconductor device according to one or more embodiments.

In one or more embodiments, referring to FIGS. 4A and 4B, each of the local bit lines LBL may be connected to memory cells MC arranged in the vertical direction Z among the memory cells MC. Each of the local bit lines LBL may be a pillar shape extending in the vertical direction Z.

The global bit lines GBL may include first global bit lines GBL1a and second global bit lines GBL2a.

Each of the first global bit lines GBL1a may include a first bit line portion, and each of the second global bit lines GBL2a may include a second bit line portion disposed at a higher level than the first bit line portions of the first global bit lines GBL1a. Each of the first global bit lines GBL1a may include a line portion disposed at a level different from a level of the line portions of each of the second global bit lines GBL2a. For example, the first global bit lines GBL1a may be disposed at a level different from a level of the second global bit lines GBL2a.

The second global bit lines GBL2a may be disposed at a higher level than the first global bit lines GBL1a.

Each of the first global bit lines GBL1a may be connected to two first local bit lines LBL1 among the local bit lines LBL, and each of the second global bit lines GBL2a may be connected to two second local bit lines LBL2 among the local bit lines LBL.

In one or more embodiments, the semiconductor device 1 may further include bit line contact plugs BLC1 and bit line contact structures BLC2.

The bit line contact plugs BLC1 may be disposed between the first local bit lines LBL1 and the first global bit lines GBL1a. Each of the first global bit lines GBL1a may be connected to the first local bit lines LBL1 by the bit line contact plugs BLC1. The bit line contact plugs BLC1 may have a lower surface connected to the first local bit lines LBL1 and an upper surface connected to the first global bit lines GBL1a.

The bit line contact structures BLC2 may be disposed between the second local bit lines LBL2 and the second global bit lines GBL2a. Each of the second global bit lines GBL2a may be connected to the second local bit lines LBL2 by the bit line contact structures BLC2.

Each of the bit line contact structures BLC2 may include a lower contact plug LLC, an intermediate contact plug LMC on the lower contact plug LLC, and an upper contact plug LUC on the intermediate contact plug LMC.

The lower contact plugs LLC may be disposed at the same level as the bit line contact plugs BLC1. The lower contact plugs LLC may be formed of the same material as the bit line contact plugs BLC1. The lower contact plugs LLC may be connected to the second local bit lines LBL2.

The intermediate contact plugs LMC may be disposed at the same level as the first global bit lines GBL1a. The intermediate contact plugs LMC may be formed of the same material as the first global bit lines GBL1a. The intermediate contact plugs LMC may be connected to the lower contact plugs LLC. The upper contact plugs LUC may be disposed between the second global bit lines GBL2a and the intermediate contact plugs LMC. The upper contact plugs LUC may be connected to the second global bit lines GBL2a and the intermediate contact plugs LMC

The routing interconnection structures RI may include first routing interconnection structures RI1 and second routing interconnection structures RI2, connected to the first global bit lines GBL1a and the second global bit lines GBL2a, respectively.

Each of the first routing interconnection structures RI1 may include a first lower routing interconnection portion RI1a. Each of the first lower routing interconnection portions RI1a of the first routing interconnection structures RI1 may include a first plug pattern BUC1 connected to a corresponding first global bit line among the first global bit lines GBL1a, and a first pad pattern PD1 disposed at a higher level than the global bit lines GBL and connected to the first plug pattern BUC1.

Each of the first plug patterns BUC1 may include a lower plug pattern ULC, an intermediate plug pattern UMC disposed on the lower plug pattern ULC and connected to the lower plug pattern ULC, and an upper plug pattern UUC disposed on the intermediate plug pattern UMC and connected to the intermediate plug pattern UMC.

In each of the first plug patterns BUC1, the lower plug pattern ULC may be connected to a corresponding first global bit line GBL1a among the first global bit lines GBL1a, and the intermediate plug pattern UMC may be disposed at the same level as the second global bit lines GBL2a. The intermediate plug patterns UMC may be formed of the same material as the second global bit lines GBL2a.

Each of the first pad patterns PD1 may include a first pad portion PD1a vertically overlapping and connected to a corresponding first plug pattern BUC1 among the first plug patterns BUC1, a second pad portion PD1b extending from the first pad portion PD1a, and a third pad portion PD1c extending from the second pad portion PD1b. In each of the first pad patterns PD1, a width of the third pad portion PD1c may be greater than a width of the second pad portion PD1b. The third pad portions PD1c may not vertically overlap the first global bit lines GBL1a.

Each of the second routing interconnection structures RI2 may include a second lower routing interconnection portion RI2a. Each of the second lower routing interconnection portions RI2a of the second routing interconnection structures RI2 may include a second plug pattern BUC2 connected to a corresponding second global bit line GBL2a among the second global bit lines GBL2a, and a second pad pattern PD2 disposed at a higher level than the global bit lines GBL and connected to the second plug pattern BUC2.

The second plug patterns BUC2 may be disposed at the same level as the upper plug patterns UUC. The second plug patterns BUC2 may be formed of the same material as the upper plug patterns UUC.

Each of the second pad patterns PD2 may include a fourth pad portion PD2a vertically overlapping and connected to a corresponding second plug pattern BUC2 among the second plug patterns BUC2, a fifth pad portion PD2b extending from the fourth pad portion PD2a, and a sixth pad portion PD2c extending from the fifth pad portion PD2b. In each of the second pad patterns PD2, a width of the sixth pad portion PD2c may be greater than a width of the fifth pad portion PD2b. The sixth pad portions PD2c may not vertically overlap the second global bit lines GBL2a.

In one or more embodiments, the first global bit lines GBL1a may include the first global bit line (GBL_1 in FIG. 2B) or the third global bit line (GBL_3 in FIG. 2B) described above. For example, the first global bit line (GBL_1 in FIG. 2B) and/or the third global bit line (GBL_3 in FIG. 2B) described above may be formed by the first global bit lines GBL1a as in FIGS. 4A and 4B.

In one or more embodiments, the second global bit lines GBL2a may be formed by the second global bit line (GBL_2 in FIG. 2B) or the fourth global bit line (GBL_4 in FIG. 2B) described above. For example, the second global bit line (GBL_2 in FIG. 2B) and/or the fourth global bit line (GBL_4 in FIG. 2B) described above may be formed by the second global bit lines GBL2a as in FIGS. 4A and 4B.

One or more embodiments in which each of the global bit lines GBL described above is connected to three local bit lines LBL will be described with reference to FIGS. 5A and 5B. FIG. 5A is a diagram illustrating a semiconductor device according to one or more embodiments, and FIG. 5B is a perspective diagram illustrating a semiconductor device according to one or more embodiments.

In one or more embodiments, referring to FIGS. 5A and 5B, the first global bit lines GBL1a illustrated in FIGS. 4A and 4B may be replaced with the first global bit lines GBL1b as in FIGS. 5A and 5B, and the second global bit lines GBL2a illustrated in FIGS. 4A and 4B may be replaced with the second global bit lines GBL2b as in FIGS. 5A and 5B.

The first global bit lines GBL1b may be disposed at a level different from a level of the second global bit lines GBL2b. The second global bit lines GBL2b may be disposed at a higher level than the first global bit lines GBL1b.

Each of the first global bit lines GBL1b may be connected to three first local bit lines LBL1 among the local bit lines LBL, and each of the second global bit lines GBL2b may be connected to three second local bit lines LBL2 among the local bit lines LBL.

Each of the first global bit lines GBL1b may be connected to the first local bit lines LBL1 by the bit line contact plugs BLC1 as illustrated in FIGS. 4A and 4B.

Each of the second global bit lines GBL2b may be connected to the second local bit lines LBL2 by the bit line contact structures BLC2 as illustrated in FIGS. 4A and 4B. For example, each of the bit line contact structures BLC2 may include the lower contact plug LLC, the intermediate contact plug LMC, and the upper contact plug LUC as illustrated in FIGS. 4A and 4B. The first and second global bit lines GBL1b and GBL2b may be connected to the routing interconnection structures RI as illustrated in FIG. 4B.

One or more embodiments in which each of the global bit lines GBL described above is connected to four local bit lines LBL will be described with reference to FIGS. 6A and 6B. FIG. 6A is a diagram illustrating a semiconductor device according to one or more embodiments, and FIG. 6B is a perspective diagram illustrating a semiconductor device according to one or more embodiments.

In one or more embodiments, referring to FIGS. 6A and 6B, the first global bit lines GBL1a illustrated in FIGS. 4A and 4B may be replaced with the first global bit lines GBL1c as in FIGS. 6A and 6B, and the second global bit lines GBL2a illustrated in FIGS. 4A and 4B may be replaced with the second global bit lines GBL2c as in FIGS. 6A and 6B.

The first global bit lines GBL1c may be disposed at a level different from a level of the second global bit lines GBL2c. The second global bit lines GBL2c may be disposed at a higher level than the first global bit lines GBL1c.

Each of the first global bit lines GBL1c may be connected to four first local bit lines LBL1 among the local bit lines LBL, and each of the second global bit lines GBL2c may be connected to four second local bit lines LBL2 among the local bit lines LBL.

Each of the first global bit lines GBL1c may be connected to the first local bit lines LBL1 by the bit line contact plugs BLC1 as illustrated in FIGS. 4A and 4B.

Each of the second global bit lines GBL2c may be connected to the second local bit lines LBL2 by the bit line contact structures BLC2 as illustrated in FIGS. 4A and 4B. For example, each of the bit line contact structures BLC2 may include the lower contact plug LLC, the intermediate contact plug LMC, and the upper contact plug LUC as illustrated in FIGS. 4A and 4B.

The first and second global bit lines GBL1c and GBL2c may be connected to the routing interconnection structures RI as illustrated in FIG. 4B.

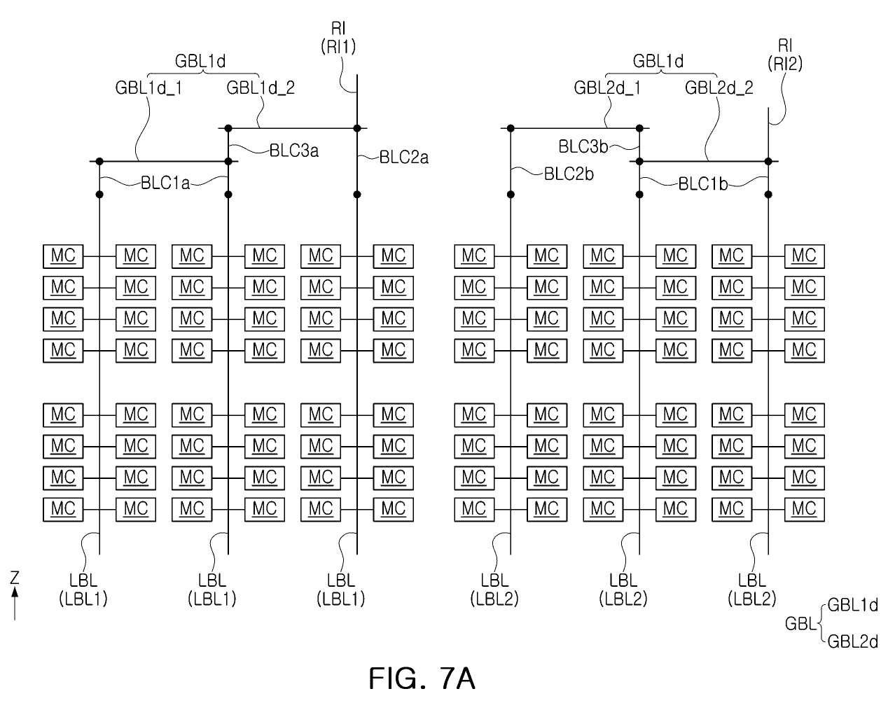

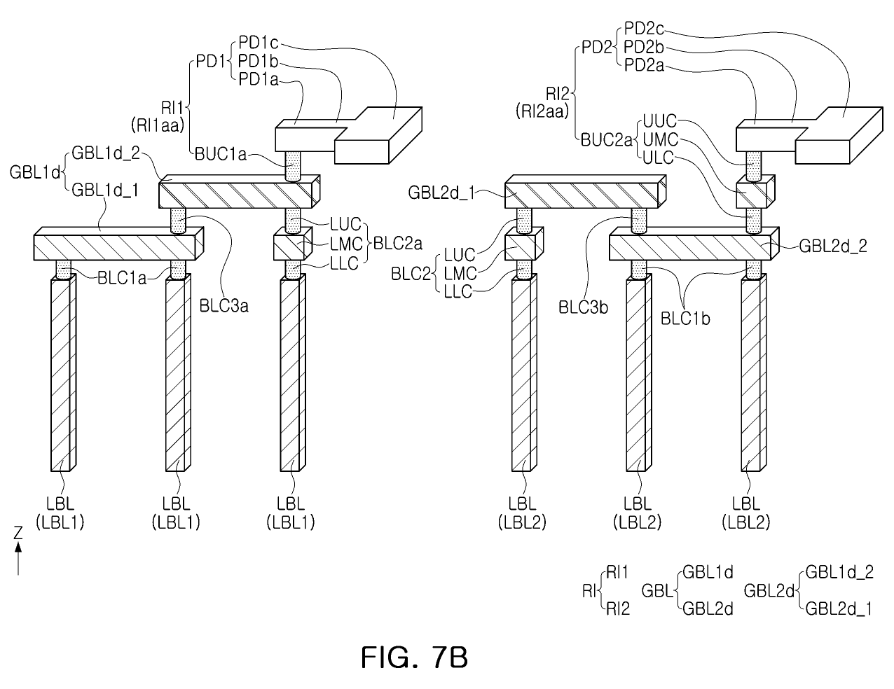

One or more embodiments in which the global bit lines GBL are connected to three local bit lines LBL will be described with reference to FIGS. 7A and 7B. FIG. 7A is a diagram illustrating a semiconductor device according to one or more embodiments, and FIG. 7B is a perspective diagram illustrating a semiconductor device according to one or more embodiments.

In one or more embodiments, referring to FIGS. 7A and 7B, the first global bit lines GBL1b illustrated in FIGS. 5A and 5B may be replaced with first global bit lines GBL1d as in FIGS. 7A and 7B, and the second global bit lines GBL2b illustrated in FIGS. 5A and 5B may be replaced with second global bit lines GBL2d as in FIGS. 7A and 7B.

Each of the first global bit lines GBL1d may be connected to three first local bit lines LBL1 among the local bit lines LBL, and each of the second global bit lines GBL2d may be connected to three second local bit lines LBL2 among the local bit lines LBL.

Each of the first global bit lines GBL1d may include a 1-1 global bit line GBL1d_1 and a 1-2 global bit line GBL1d_2 disposed at different levels.

In each of the first global bit lines GBL1d, the 1-1 global bit line GBL1d_1 may be referred to as the 1-1 bit line portion GBL1d_1, and the 1-2 global bit line GBL1d_2 may be referred to as the 1-2 bit line portion GBL1d_2.

In each of the first global bit lines GBL1d, the 1-2 bit line portion GBL1d_2 may be disposed at a higher level than the 1-1 bit line portion GBL1d_1.

In each of the first global bit lines GBL1d, the 1-2 bit line portion GBL1d_2 may have substantially the same length as a length of the 1-1 bit line portion GBL1d_1.

In each of the first global bit lines GBL1d, the 1-1 bit line portion GBL1d_1 and the 1-2 bit line portion GBL1d_2 may vertically overlap each other on the first local bit line LBL1 positioned in the middle of the first local bit lines LBL1 connected to the first global bit line GBL1d, and may be electrically connected to each other by the first intermediate contact plug BLC3a.

In each of the first global bit lines GBL1d, the 1-1 (first) bit line portion GBL1d_1 may be connected to an x number of first local bit lines LBL1 of the first local bit lines LBL1 by the first bit line contact plugs BLC1a, and the 1-2 (second) bit line portion GBL1d_2 may be connected to an y number of first local bit lines LBL1 of the first local bit lines LBL1 by the first bit line contact structure BLC2a. In one or more embodiments, x and y may be different natural numbers. In one or more embodiments, x may be 2, and y may be 1.

The first bit line contact plugs BLC1a may have the same shape and the same structure as those of the bit line contact plugs BLC1 illustrated in FIG. 4B. The first bit line contact structure BLC2a may have the same shape and the same structure as those of each of the bit line contact structures BLC2 illustrated in FIG. 4B.

Each of the second global bit lines GBL2d may include a 2-1 global bit line GBL2d_1 and a 2-2 global bit line GBL2d_2 disposed at different levels.

In each of the second global bit lines GBL2d, the 2-1 global bit line GBL2d_1 may be referred to as the 2-1 (first) bit line portion GBL2d_1, and the 2-2 global bit line GBL2d_2 may be referred to as the 2-2 (second) bit line portion GBL2d_2.

In each of the second global bit lines GBL2d, the 2-1 bit line portion GBL2d_1 may be disposed at a higher level than the 2-2 bit line portion GBL2d_2.

In each of the second global bit lines GBL2d, the 2-1 bit line portion GBL2d_1 may have substantially the same length as that of the 2-2 bit line portion GBL2d_2.

In each of the second global bit lines GBL2d, the 2-1 bit line portion GBL2d_1 and the 2-2 bit line portion GBL2d_2 may vertically overlap each other on the second local bit line LBL2 positioned in the middle of the second local bit lines LBL2 connected to the second global bit line GBL2d, and may be electrically connected to each other by the second intermediate contact plug BLC3b.

In each of the second global bit lines GBL2d, the 2-1 bit line portion GBL2d_1 may be connected to the y number of second local bit lines LBL2 of the second local bit lines LBL2 by the second bit line contact structure BLC2b, and the 2-2 bit line portion GBL2d_2 may be connected to the x number of second local bit lines LBL2 of the second local bit lines LBL2 by the second bit line contact plugs BLC1b. As described above, the x may be 2, and the y may be 1.

The second bit line contact plugs BLC1b may have the same shape and the same structure as those of the bit line contact plugs BLC1 illustrated in FIG. 4B. The second bit line contact structure BLC2b may have the same shape and the same structure as those of each of the bit line contact structures BLC2 illustrated in FIG. 4B.

The first and second global bit lines GBL1d and GBL2d may be connected to the routing interconnection structures RI.

Each of the first routing interconnection structures RI1 of the routing interconnection structures RI may include a third lower routing interconnection portion RI1aa. The third lower routing interconnection portion RI1aa may be connected to the 1-2 bit line portion GBL1d_2 of the first global bit line GBL1d.

Each of the second routing interconnection structures RI2 of the routing interconnection structures RI may include a fourth lower routing interconnection portion RI2aa. The fourth lower routing interconnection portion RI2aa may be connected to the 2-2 bit line portion GBL2d_2 of the second global bit line GBL2d.

The third lower routing interconnection portion RI1aa may include a first plug pattern BUC1a connected to the 1-2 bit line portion GBL1d_2 of the first global bit line GBL1d, and the first pad pattern PD1 disposed at a higher level than the global bit lines GBL and connected to the first plug pattern BUC1a, as illustrated in FIG. 4B. The fourth lower routing interconnection portion RI2aa may include a second plug pattern BUC2a connected to the 2-2 bit line portion GBL2d_2 of the second global bit line GBL2d, and the second pad pattern PD2 disposed at a higher level than the global bit lines GBL and connected to the second plug pattern BUC2a, as illustrated in FIG. 4B.

The first plug pattern BUC1a may have substantially the same shape and the same structure as those of the second plug pattern BUC2 in FIG. 4B. The second plug pattern BUC2a may have substantially the same shape and the same structure as those of the first plug pattern BUC1 in FIG. 4B.

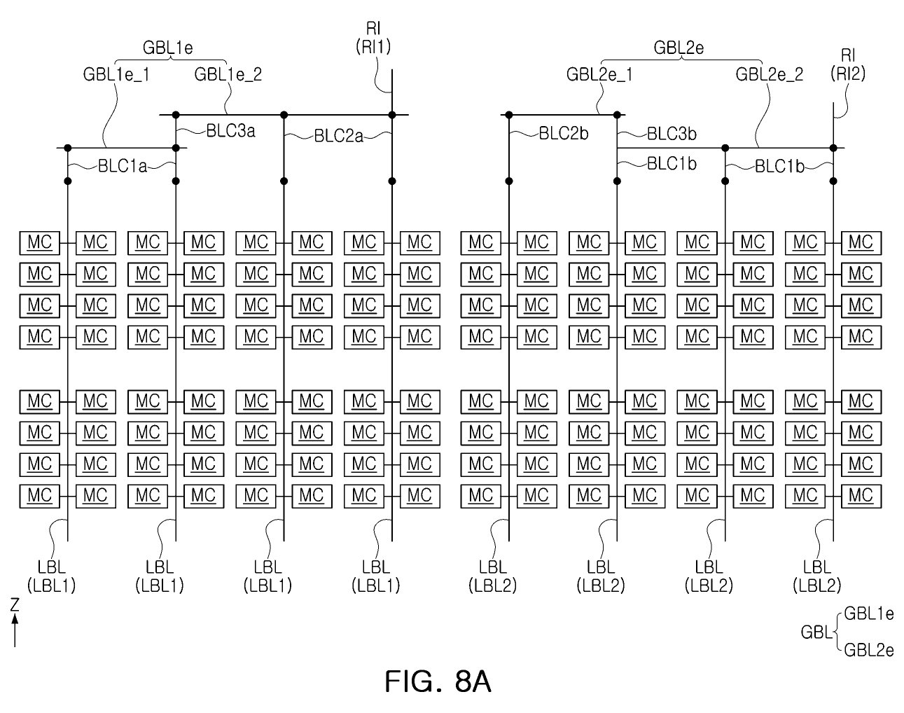

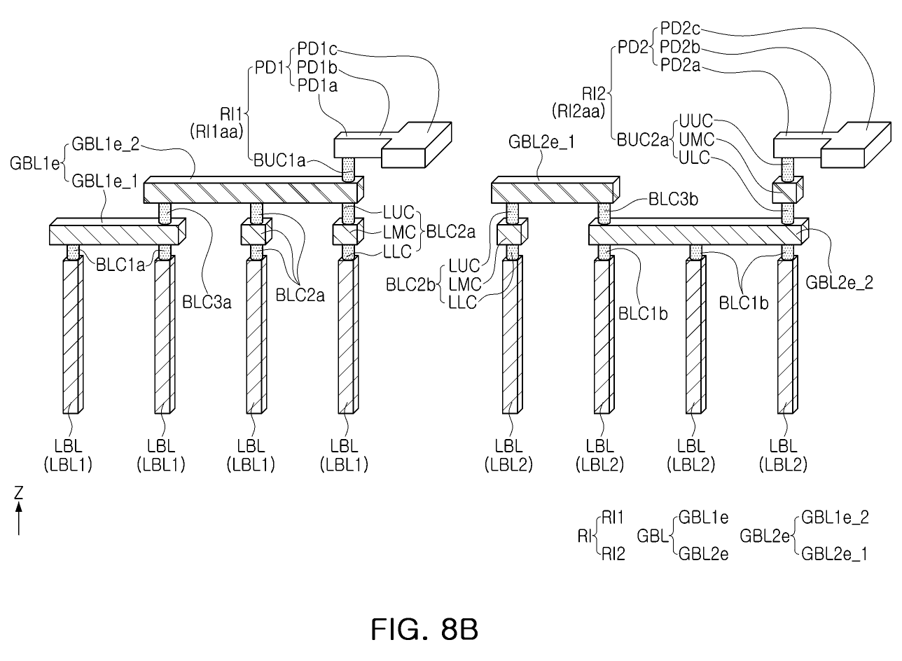

One or more embodiments in which the global bit lines GBL are connected to four local bit lines LBL will be described with reference to FIGS. 8A and 8B. FIG. 8A is a diagram illustrating a semiconductor device according to one or more embodiments, and FIG. 8B is a perspective diagram illustrating a semiconductor device according to one or more embodiments.

In one or more embodiments, referring to FIGS. 8A and 8B, the first global bit lines GBL1c illustrated in FIGS. 6A and 6B may be replaced with first global bit lines GBL1e as in FIGS. 8A and 8B, and the second global bit lines GBL2c illustrated in FIGS. 6A and 6B may be replaced with second global bit lines GBL2e as in FIGS. 8A and 8B.

Each of the first global bit lines GBL1e may be connected to four first local bit lines LBL1 among the local bit lines LBL, and each of the second global bit lines GBL2e may be connected to four second local bit lines LBL2 among the local bit lines LBL.

Each of the first global bit lines GBL1e may include a 1-1 global bit line GBL1e_1 and a 1-2 global bit line GBL1e_2 disposed at different levels.

In each of the first global bit lines GBL1e, the 1-1 global bit line GBL1e_1 may be referred to as 1-1 bit line portion GBL1e_1, and the 1-2 global bit line GBL1e_2 may be referred to as 1-2 bit line portion GBL1e_2.

In each of the first global bit lines GBL1e, the 1-2 bit line portion GBL1e_2 may be disposed at a higher level than the 1-1 bit line portion GBL1e_1.

In each of the first global bit lines GBL1e, the 1-2 bit line portion GBL1e_2 may have a length greater than a length of the 1-1 bit line portion GBL1e_1.

In each of the first global bit lines GBL1e, the 1-1 bit line portion GBL1e_1 and the 1-2 bit line portion GBL1e_2 may vertically overlap each other on one first local bit line LBL1 and may be electrically connected to each other by the first intermediate contact plug BLC3a.

In each of the first global bit lines GBL1e, the 1-1 bit line portion GBL1e_1 may be connected to an xa number of first local bit lines LBL1 among the first local bit lines LBL1 by the first bit line contact plugs BLC1a as illustrated in FIG. 7B, and the 1-2 bit line portion GBL1e_2 may be connected to an ya number of first local bit lines LBL1 among the first local bit lines LBL1 by the first bit line contact structures BLC2a as illustrated in FIG. 7B. In one or more embodiments, xa and ya may be the same natural numbers. In one or more embodiments, each of xa and ya may be 2.

Each of the second global bit lines GBL2e may include a 2-1 global bit line GBL2e_1 and a 2-2 global bit line GBL2e_2, disposed at different levels.

In each of the second global bit lines GBL2e, the 2-1 global bit line GBL2e_1 may be referred to as 2-1 bit line portion GBL2e_1, and the 2-2 global bit line GBL2e_2 may be referred to as 2-2 bit line portion GBL2e_2.

In each of the second global bit lines GBL2e, the 2-1 bit line portion GBL2e_1 may be disposed at a higher level than the 2-2 bit line portion GBL2e_2.

In each of the second global bit lines GBL2e, the 2-1 bit line portion GBL2e_1 may have a length smaller than a length of the 2-2 bit line portion GBL2e_2.

In each of the second global bit lines GBL2e, the 2-1 bit line portion GBL2e_1 and the 2-2 bit line portion GBL2e_2 may vertically overlap each other on one second local bit line LBL2 and may be electrically connected to each other by a second intermediate contact plug BLC3b

In each of the second global bit lines GBL2e, the 2-1 bit line portion GBL2e_1 may be connected to an xb number of second local bit lines LBL2 among the second local bit lines LBL2 by the second bit line contact structure BLC2b as illustrated in FIG. 7B, and the 2-2 bit line portion GBL2e_2 may be connected to a yb number of second local bit lines LBL2 among the second local bit lines LBL2 by the second bit line contact plugs BLC1b as illustrated in FIG. 7B. The xb and yb may be different natural numbers. yb may be greater than xb. For example, yb may be 3, and xb may be 1.

The first and second global bit lines GBL1e and GBL2e may be connected to the routing interconnection structures RI. Each of the first routing interconnection structures RI1 of the routing interconnection structures RI may include the third lower routing interconnection portion RI1aa as illustrated in FIG. 7B. The third lower routing interconnection portion RI1aa may be connected to the 1-2 bit line portion GBL1e_2 of the first global bit line GBL1e. The second routing interconnection structures RI2 of the routing interconnection structures RI may include the fourth lower routing interconnection portion RI2aa as illustrated in FIG. 7B. The fourth lower routing interconnection portion RI2aa may be connected to the 2-2 bit line portion GBL2e_2 of the second global bit line GBL2e.

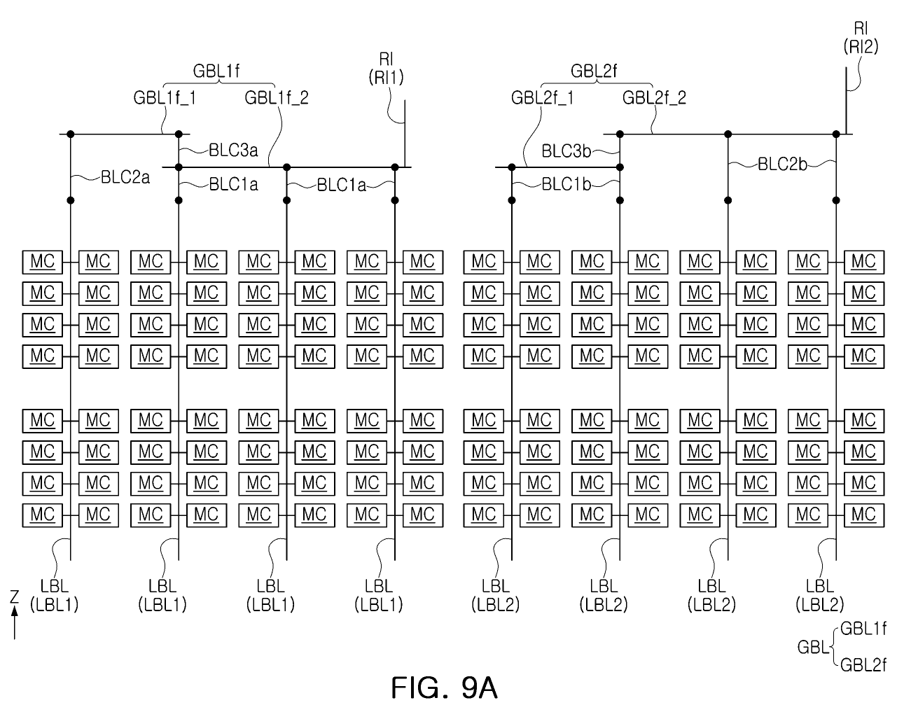

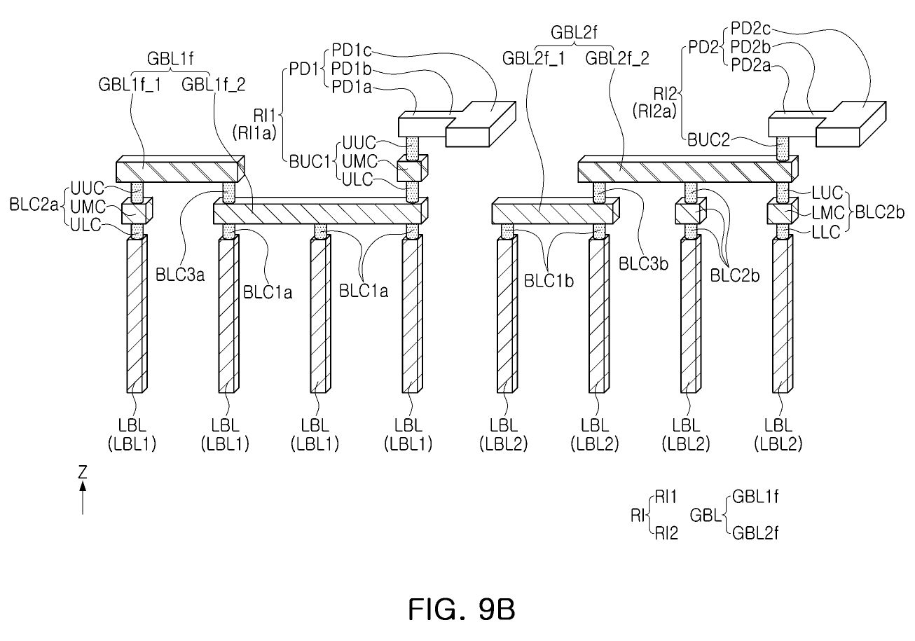

One or more embodiments in which the global bit lines GBL are connected to four local bit lines LBL will be described with reference to FIGS. 9A and 9B. FIG. 9A is a diagram illustrating a semiconductor device according to one or more embodiments, and FIG. 9B is a perspective diagram illustrating a semiconductor device according to one or more embodiments.

In one or more embodiments, referring to FIGS. 9A and 9B, the first global bit lines GBL1c illustrated in FIGS. 6A and 6B may be replaced with first global bit lines GBL1f as in FIGS. 9A and 9B, and the second global bit lines GBL2c illustrated in FIGS. 6A and 6B may be replaced with second global bit lines GBL2f as in FIGS. 9A and 9B.

Each of the first global bit lines GBL1f may be connected to four first local bit lines LBL1 among the local bit lines LBL, and each of the second global bit lines GBL2f may be connected to four second local bit lines LBL2 among the local bit lines LBL.

Each of the first global bit lines GBL1f may include a 1-1 global bit line GBL1f_1 and a 1-2 global bit line GBL1f_2 disposed at different levels.

In each of the first global bit lines GBL1f, the 1-1 global bit line GBL1f_1 may be referred to as the 1-1 bit line portion GBL1f_1, and the 1-2 global bit line GBL1f_2 may be referred to as the 1-2 bit line portion GBL1f_2.

In each of the first global bit lines GBL1f, the 1-2 bit line portion GBL1f_2 may be disposed at a lower level than the 1-1 bit line portion GBL1f_1.

In each of the first global bit lines GBL1f, the 1-1 bit line portion GBL1f_1 and the 1-2 bit line portion GBL1f_2 may vertically overlap each other on one first local bit line LBL1 and may be electrically connected to each other by the first intermediate contact plug BLC3a.

In each of the first global bit lines GBL1f, the 1-1 bit line portion GBL1f_1 may be connected to an xc number of first local bit lines LBL1 among the first local bit lines LBL1 by the first bit line contact structure BLC2a as illustrated in FIG. 7B, and the 1-2 bit line portion GBL1f_2 may be connected to a yc number of first local bit lines LBL1 among the first local bit lines LBL1 by the first bit line contact plugs BLC1a as illustrated in FIG. 7B. In one or more embodiments, xc and yc may be different natural numbers. yc may be greater than xc. In one or more embodiments, xc may be 1, and yc may be 3.

Each of the second global bit lines GBL2f may include a 2-1 global bit line GBL2f_1 and a 2-2 global bit line GBL2f_2 disposed at different levels.

In each of the second global bit lines GBL2f, the 2-1 global bit line GBL2f_1 may be referred to as 2-1 bit line portion GBL2f_1, and the 2-2 global bit line GBL2f_2 may be referred to as 2-2 bit line portion GBL2f_2.

In each of the second global bit lines GBL2f, the 2-1 bit line portion GBL2f_1 may be disposed at a lower level than the 2-2 bit line portion GBL2f_2

In each of the second global bit lines GBL2f, the 2-1 bit line portion GBL2f_1 and the 2-2 bit line portion GBL2f_2 may vertically overlap each other on one second local bit line LBL2 and may be electrically connected to each other by a second intermediate contact plug BLC3b.

In each of the second global bit lines GBL2f, the 2-1 bit line portion GBL2f_1 may be connected to an xd number of second local bit lines LBL2 among the second local bit lines LBL2 by the second bit line contact plugs BLC1b as illustrated in FIG. 7B, and the 2-2 bit line portion GBL2f_2 may be connected to a yd number of second local bit lines LBL2 among the second local bit lines LBL2 by the second bit line contact structures BLC2b as illustrated in FIG. 7B. xd and yd may be the same natural number. For example, xd and yd may be 2.

The first and second global bit lines GBL1f and GBL2f may be connected to the routing interconnection structures RI. The first routing interconnection structure RI1 of the routing interconnection structures RI may include the first lower routing interconnection portion RI1a as illustrated in FIG. 6B. The first lower routing interconnection portion RI1a may be connected to the 1-2 bit line portion GBL1f_2 of the first global bit line GBL1f. The second routing interconnection structures RI2 of the routing interconnection structures RI may include the second lower routing interconnection portion RI2a as illustrated in FIG. 6B. The second lower routing interconnection portion RI2a may be connected to the 2-2 bit line portion GBL2f_2 of the second global bit line GBL2f.

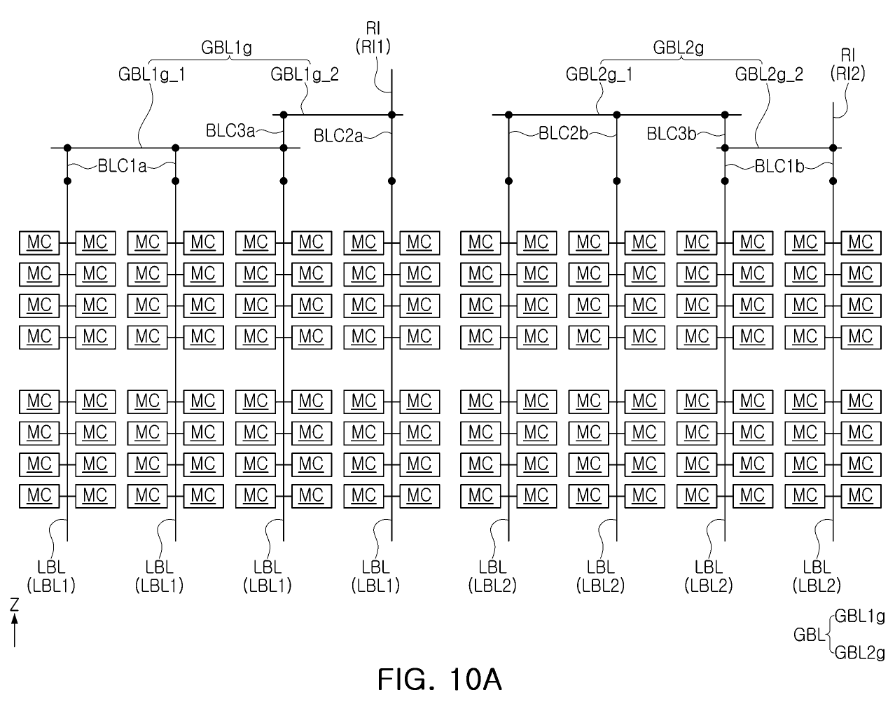

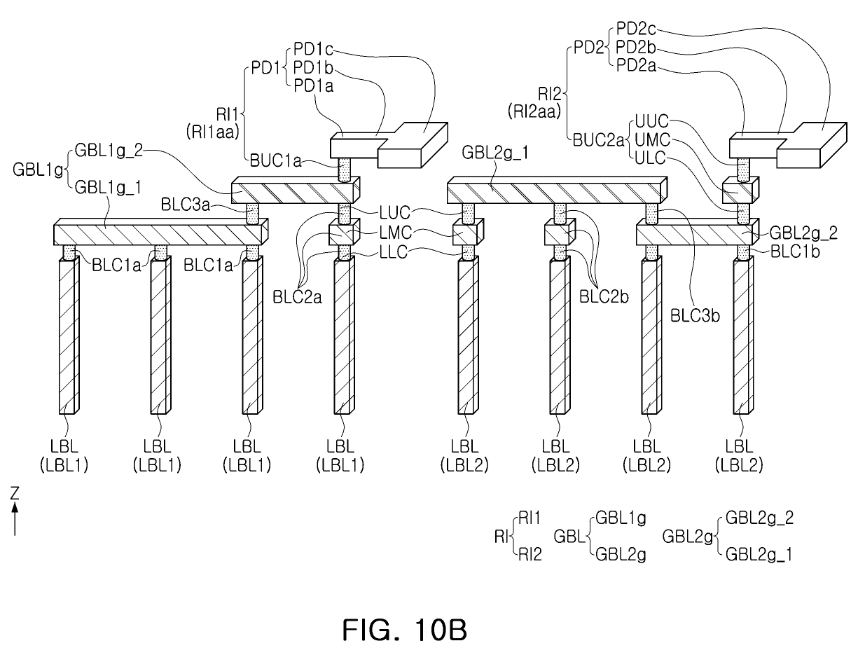

One or more embodiments in which the global bit lines GBL are connected to four local bit lines LBL will be described with reference to FIGS. 10A and 10B. FIG. 10A is a diagram illustrating a semiconductor device according to one or more embodiments, and FIG. 10B is a perspective diagram illustrating a semiconductor device according to one or more embodiments.

In one or more embodiments, referring to FIGS. 10A and 10B, the first global bit lines GBL1e illustrated in FIGS. 8A and 8B may be replaced with first global bit lines GBL1g as in FIGS. 10A and 10B, and the second global bit lines GBL2e illustrated in FIGS. 8A and 8B may be replaced with second global bit lines GBL2g as in FIGS. 10A and 10B.

The 1-1 bit line portion GBL1e_1 illustrated in FIGS. 8A and 8B may be replaced with the 1-1 bit line portion GBL1g_1 having an increased length, and the 1-2 bit line portion GBL1e_2 illustrated in FIGS. 8A and 8B may be replaced with the 1-2 bit line portion GBL1g_2 having a decreased length. The length of the 1-1 bit line portion GBL1g_1 may be greater than the length of the 1-2 bit line portion GBL1g_2. Accordingly, each of the first global bit lines GBL1g may include the 1-1 bit line portion GBL1g_1 and the 1-2 bit line portion GBL1g_2.

In each of the first global bit lines GBL1g, the 1-1 bit line portion GBL1g_1 and the 1-2 bit line portion GBL1g_2 may vertically overlap each other on one first local bit line LBL1 and may be electrically connected to each other by the first intermediate contact plug BLC3a.

In each of the first global bit lines GBL1g, the 1-1 bit line portion GBL1g_1 may be connected to an xe number of first local bit lines LBL1 among the first local bit lines LBL1 by the first bit line contact plugs BLC1a as illustrated in FIG. 7B, and the 1-2 bit line portion GBL1g_2 may be connected to a ye number of first local bit lines LBL1 among the first local bit lines LBL1 by the first bit line contact structure BLC2a as illustrated in FIG. 7B. xe may be greater than ye. In one or more embodiments, xe may be 3 and ye may be 1.

The 2-1 bit line portion GBL2e_1 illustrated in FIGS. 8A and 8B may be replaced with the 2-1 bit line portion GBL2g_1 having an increased length, and the 2-2 bit line portion GBL2e_2 illustrated in FIGS. 8A and 8B may be replaced with the 2-2 bit line portion GBL2g_2 having a decreased length. The length of the 2-1 bit line portion GBL2g_1 may be greater than the length of the 2-2 bit line portion GBL2g_2. Accordingly, each of the second global bit lines GBL2g may include the 2-1 bit line portion GBL2g_1 and the 2-2 bit line portion GBL2g_2.

In each of the second global bit lines GBL2g, the 2-1 bit line portion GBL2g_1 and the 2-2 bit line portion GBL2g_2 may vertically overlap each other on one second local bit line LBL2 and may be electrically connected to each other by a second intermediate contact plug BLC3b.

In each of the second global bit lines GBL2g, the 2-1 bit line portion GBL2g_1 may be connected to an xf number of second local bit lines LBL2 among the second local bit lines LBL2 by the second bit line contact structures BLC2b as illustrated in FIG. 7B, and the 2-2 bit line portion GBL2g_2 may be connected to a yf number of second local bit lines LBL2 among the second local bit lines LBL2 by the second bit line contact plugs BLC1b as illustrated in FIG. 7B. xf and yf may be the same natural number. For example, xf and yf may be 2.

The first and second global bit lines GBL1g and GBL2g may be connected to the routing interconnection structures RI. The first routing interconnection structure RI1 of the routing interconnection structures RI may include the third lower routing interconnection portion RI1aa as illustrated in FIG. 8B. The third lower routing interconnection portion RI1aa may be connected to the 1-2 bit line portion GBL1g_2 of the first global bit line GBL1g. The second routing interconnection structures RI2 of the routing interconnection structures RI may include the fourth lower routing interconnection portion RI2aa as illustrated in FIG. 8B. The fourth lower routing interconnection portion RI2aa may be connected to the 2-2 bit line portion GBL2g_2 of the second global bit line GBL2g.

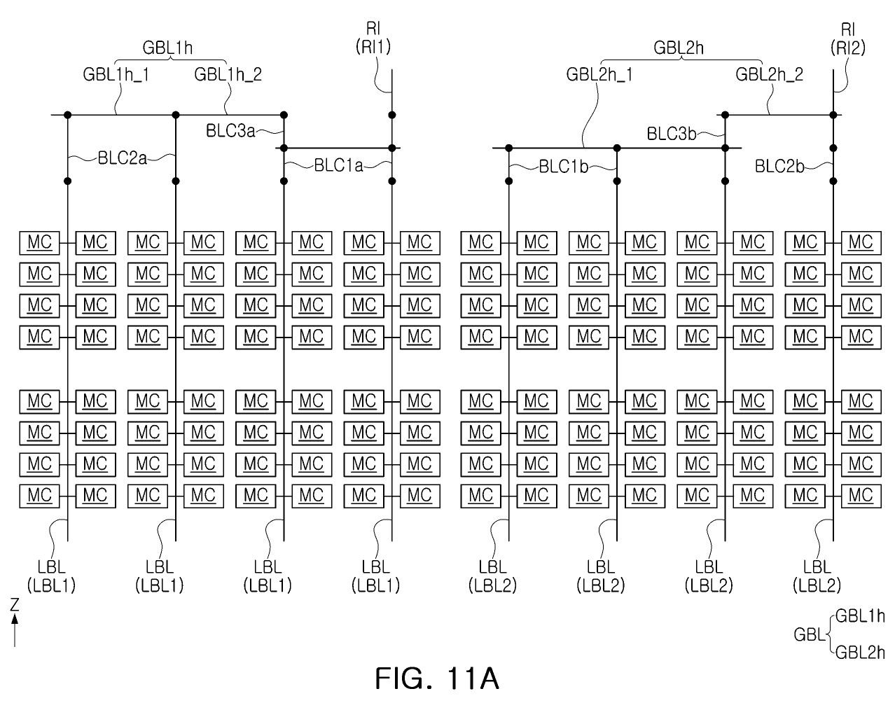

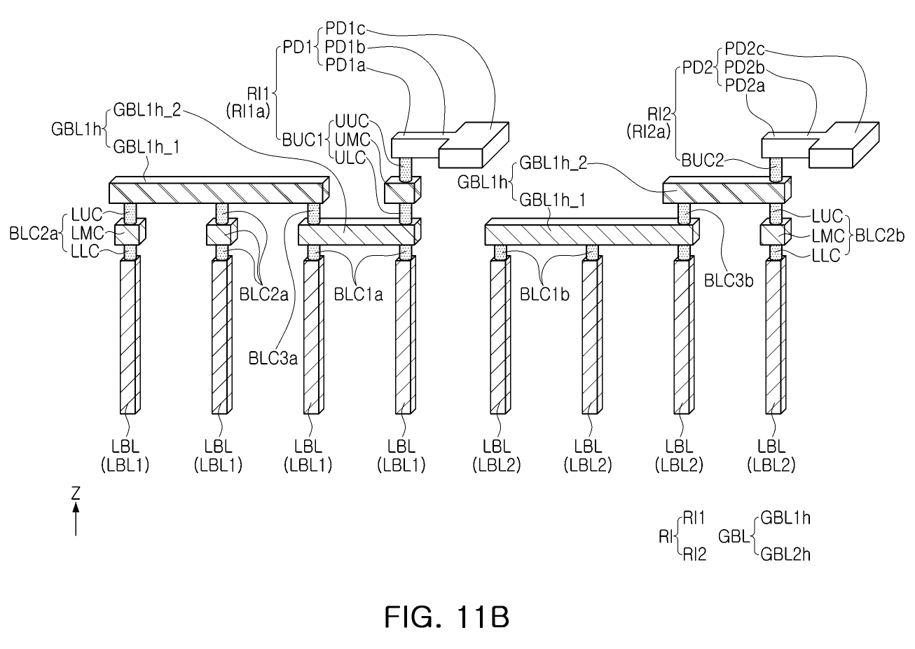

One or more embodiments in which the global bit lines GBL are connected to four local bit lines LBL will be described with reference to FIGS. 11A and 11B. FIG. 11A is a diagram illustrating a semiconductor device according to one or more embodiments, and FIG. 11B is a perspective diagram illustrating a semiconductor device according to one or more embodiments.

In one or more embodiments, referring to FIGS. 11A and 11B, the first global bit lines GBL1f illustrated in FIGS. 9A and 9B may be replaced with the first global bit lines GBL1h as in FIGS. 11A and 11B, and the second global bit lines GBL2f illustrated in FIGS. 9A and 9B may be replaced with the second global bit lines GBL2h as in FIGS. 11A and 11B.

The 1-1 bit line portion GBL1f_1 illustrated in FIGS. 9A and 9B may be replaced with the 1-1 bit line portion GBL1h_1 having an increased length, and the 1-2 bit line portion GBL1f_2 illustrated in FIGS. 9A and 9B may be replaced with the 1-2 bit line portion GBL1h_2 having a decreased length. The length of the 1-1 bit line portion GBL1h_1 may be greater than the length of the 1-2 bit line portion GBL1h_2. Accordingly, each of the first global bit lines GBL1h may include the 1-1 bit line portion GBL1h_1 and the 1-2 bit line portion GBL1h_2.

In each of the first global bit lines GBL1h, the 1-1 bit line portion GBL1h_1 and the 1-2 bit line portion GBL1h_2 may vertically overlap each other on one first local bit line LBL1 and may be electrically connected to each other by the first intermediate contact plug BLC3a.

In each of the first global bit lines GBL1h, the 1-1 bit line portion GBL1h_1 may be connected to an xg number of first local bit lines LBL1 among the first local bit lines LBL1 by the first bit line contact structure BLC2a as illustrated in FIG. 7B, and the 1-2 bit line portion GBL1h_2 may be connected to a yg number of first local bit lines LBL1 among the first local bit lines LBL1 by the first bit line contact plugs BLC1a as illustrated in FIG. 7B. In one or more embodiments, xg and yg may be 2.

The 2-1 bit line portion GBL2f_1 illustrated in FIGS. 9A and 9B may be replaced with the 2-1 bit line portion GBL2h_1 having an increased length, and the 2-2 bit line portion GBL2f_2 illustrated in FIGS. 9A and 9B may be replaced with the 2-2 bit line portion GBL2h_2 having a decreased length. The length of the 2-1 bit line portion GBL2h_1 may be greater than the length of the 2-2 bit line portion GBL2h_2. Accordingly, each of the second global bit lines GBL2h may include the 2-1 bit line portion GBL2h_1 and the 2-2 bit line portion GBL2h_2.

In each of the second global bit lines GBL2h, the 2-1 bit line portion GBL2h_1 and the 2-2 bit line portion GBL1h_2 may vertically overlap each other on one second local bit line LBL2 and may be electrically connected to each other by the second intermediate contact plug BLC3b.

In each of the second global bit lines GBL2h, the 2-1 bit line portion GBL2h_1 may be connected to an xh number of second local bit lines LBL2 among the second local bit lines LBL2 by the second bit line contact plugs BLC1b as illustrated in FIG. 7B, and the 2-2 bit line portion GBL2h_2 may be connected to a yh number of second local bit lines LBL2 among the second local bit lines LBL2 by the second bit line contact structure BLC2b as illustrated in FIG. 7B. In one or more embodiments, xh may be 3 and yh may be 1.

The first and second global bit lines GBL1h and GBL2h may be connected to the routing interconnection structures RI. The first routing interconnection structure RI1 of the routing interconnection structures RI may include the first lower routing interconnection portion RI1a as illustrated in FIG. 6B. The first lower routing interconnection portion RI1a may be connected to the 1-2 bit line portion GBL1h_2 of the first global bit line GBL1h. The second routing interconnection structures RI2 of the routing interconnection structures RI may include the second lower routing interconnection portion RI2a as illustrated in FIG. 6B. The second lower routing interconnection portion RI2a may be connected to the 2-2 bit line portion GBL2h_2 of the second global bit line GBL2h.

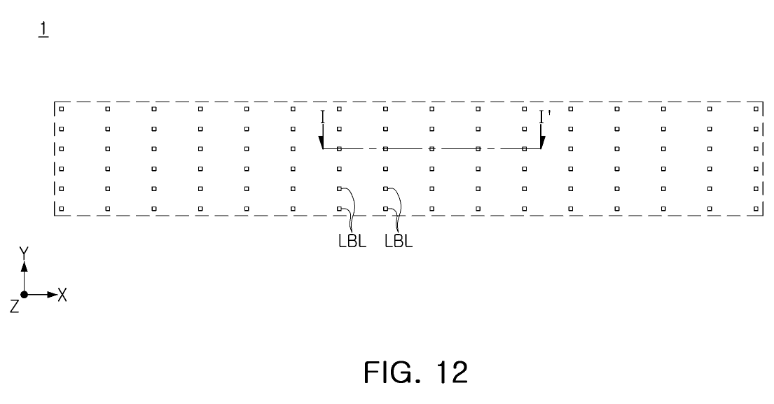

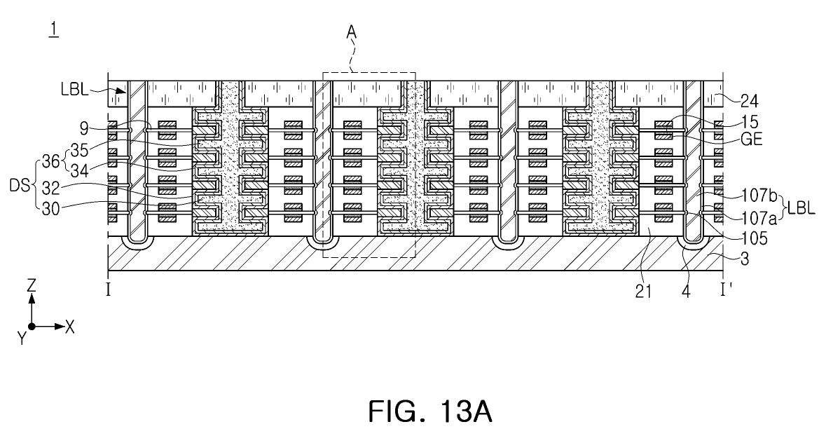

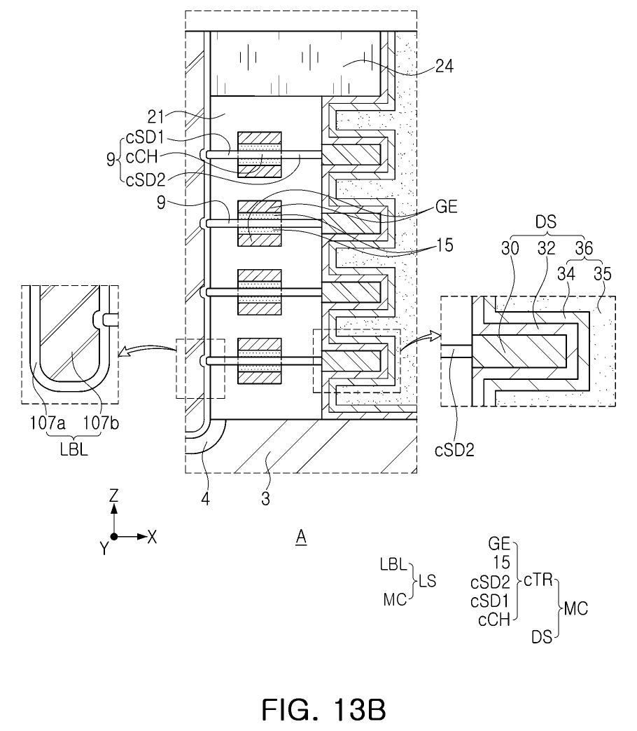

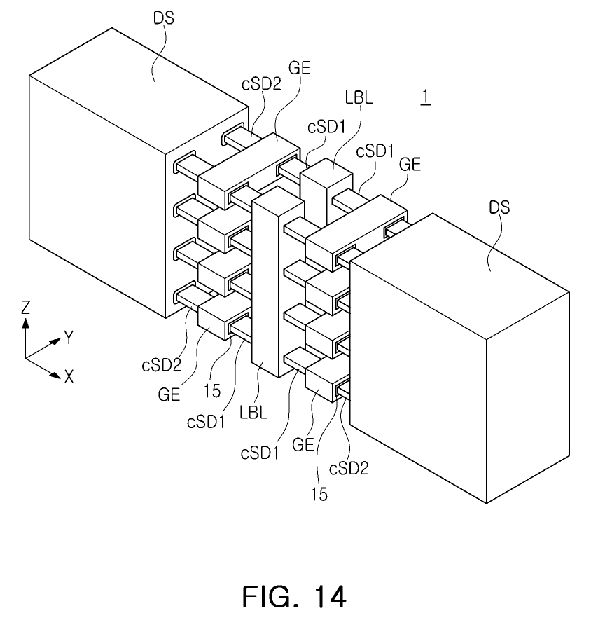

In the description below, a structure including the local bit lines LBL and the memory cells MC in a semiconductor device 1 according to example embodiments described above will be described with reference to FIGS. 12, 13A, 13B, and 14. In FIGS. 12, 13A, 13B, and 14, FIG. 12 is a plan diagram illustrating the local bit lines LBL described above, FIG. 13A is a cross-sectional diagram illustrating a region taken along line I-I’ in FIG. 12, FIG. 13B is an enlarged diagram illustrating a region indicated as “A” in FIG. 13A, and FIG. 14 is a perspective diagram illustrating a portion of the structure including the local bit lines LBL and the memory cells MC.

Referring to FIGS. 12, 13A, 13B, and 14, the first structure (ST1 in FIG. 1) of the semiconductor device 1 described above may include a lower structure LS.

The lower structure LS may include the local bit lines LBL and the memory cells MC described in the example embodiments above.

The lower structure LS may include a base 3 and active patterns 9 disposed on the base 3. The base 3 may be configured as a semiconductor substrate, but one or more embodiments thereof is not limited thereto. For example, the base 3 may be configured as an insulating substrate.

The active patterns 9 may be formed of a semiconductor material used as a channel region of a transistor. For example, each of the active patterns 9 may include a single crystal silicon semiconductor, an oxide semiconductor, or a two-dimensional material having semiconductor properties. Each of the active patterns 9 may be a bar shape extending in the first direction X. Each of the active patterns 9 may include a first source/drain region cSD1 and a second source/drain region cSD2 spaced apart from each other in the first direction X, and a channel region cCH between the first and second source/drain regions cSD1 and cSD2.

The lower structure LS may include cell gate electrodes GE vertically overlapping the channel regions cCH, and cell gate dielectric layers 15 between the cell gate electrodes GE and the channel regions cCH. The cell gate electrodes GE may be stacked and spaced apart from each other in the vertical direction Z. Each of the cell gate electrodes GE may surround a corresponding channel region cCH among the channel regions cCH and may extend in the second direction Y perpendicular to the first direction X. The cell gate electrodes GE may be word lines.

The first and second directions X and Y may be parallel to an upper surface of the base 3. The vertical direction Z may be perpendicular to an upper surface of the base 3.

In example embodiments, each of the memory cells MC described above may include a cell transistor cTR and a data storage structure DS. The data storage structure DS may be configured as a cell capacitor for storing data in a memory such as a DRAM.

In example embodiments, each of the cell transistors cTR may include the channel region cCH, the first and second source/drain regions SD1 and SD2, the cell gate dielectric layer 15 and the cell gate electrode GE.

In example embodiments, each of the data storage structures DS may include a first electrode 30 connected to a corresponding second source/drain region cSD2 of the second source/drain regions cSD2, a second electrode 36 covering the first electrode 30, and a dielectric layer 32 between the first electrode 30 and the second electrode 36. The second electrodes 36 may be plate electrodes.

In each of the data storage structures DS, the first electrode 30 may have a pillar shape extending in the first direction X, and the second electrode 36 may include a first electrode material layer 34 in contact with the dielectric layer 32 and a second electrode material layer 35 in contact with the first electrode material layer 34. In one or more embodiments, the shape of the first electrode 30 is not limited to a pillar shape. For example, the first electrode 30 may have a cylinder shape.

In the data storage structures DS, a lower surface of each of the second electrodes 36 may be disposed at a lower level than a lowermost cell transistor among the cell transistors cTR, and an upper surface of each of the second electrodes 36 may be disposed at a higher level than an uppermost cell transistor among the cell transistors cTR. Each of the second electrodes 36 may extend in the second direction Y.

The memory cells MC including the cell transistors cTR and the data storage structures DS may be arranged three-dimensionally in the vertical direction Z, the first direction X, and the second direction Y, perpendicular to each other.

The lower structure LS may include a lower insulating structure 21 disposed on the base 3 and disposed on side surfaces of the second electrodes 36. The cell transistors cTR may be buried in the lower insulating structure 21.

The lower structure LS may include a capping insulating layer 24 disposed on the lower insulating structure 21 and disposed between the second electrodes 36. The lower structure LS may include an insulating layer 4 between the local bit lines LBL and the base 3.

Each of the local bit lines LBL may extend in the vertical direction Z. For example, each of the local bit lines LBL may have a pillar shape extending in the vertical direction Z.

On the plane, the local bit lines LBL may be arranged in the first direction X and the second direction Y perpendicular to each other.

Side surfaces of the local bit lines LBL may be connected to the memory cells MC.

The side surfaces of the local bit lines LBL may be connected to the first source/drain regions cSD1 of the cell transistors cTR of the first memory cells MC.

The local bit lines LBL may have recessed side surfaces in contact with the memory cells MC.

Each of the local bit lines LBL may be a pillar shape extending from a level lower than a level of the channel region cCH of the cell transistor cTR of the lowermost memory cell among the memory cells MC to a level higher than a level of the channel region cCH of the cell transistor cTR of the uppermost memory cell among the memory cells MC.

Each of the local bit lines LBL may include a pillar pattern 107b and a conductive liner 107a covering a side surface and a lower surface of the pillar pattern 107b. The conductive liner 107a may include at least one of doped polysilicon, a metal-semiconductor compound, and a metal nitride. For example, the conductive liner 107a may include at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, and CoSi, and the pillar pattern 107b may include a material different from the material of the conductive liner 107a and may include at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, and CoSi.

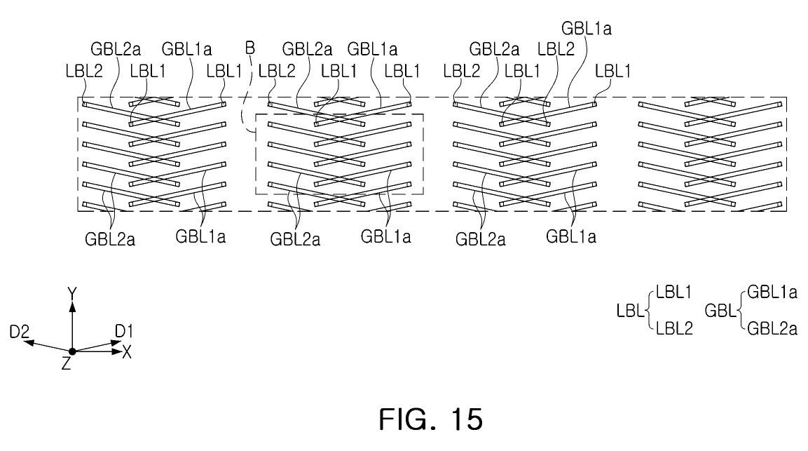

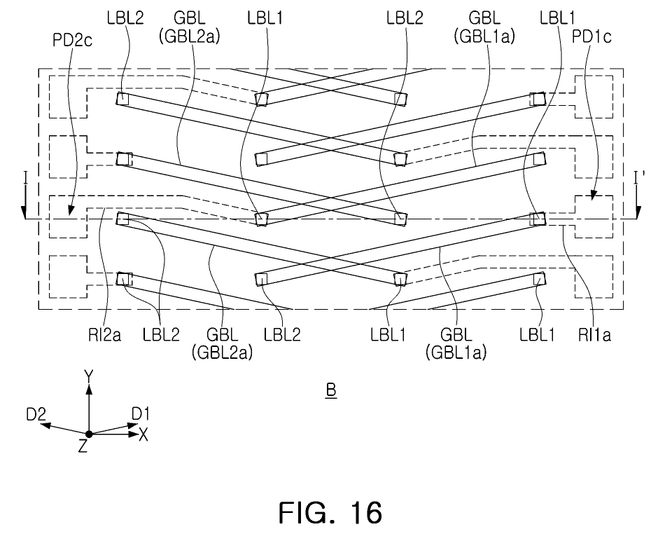

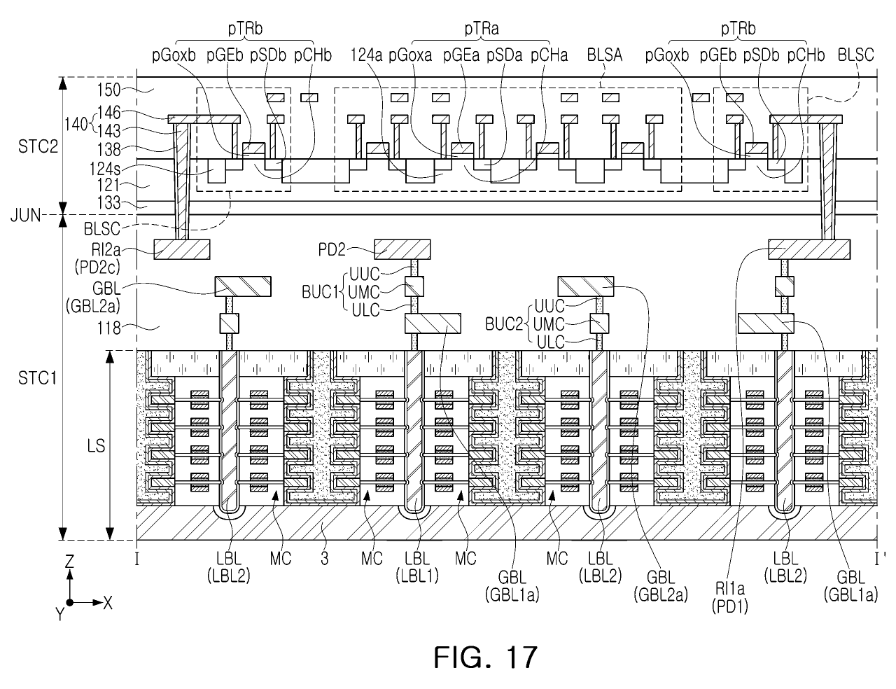

In the description below, a structure further including global bit lines GBL and peripheral circuits will be described with reference to FIGS. 15, 16, and 17, differently from the structure described with reference to FIGS. 12, 13A, 13B, and 14 above. In FIGS. 15, 16, and 17, FIG. 15 is a diagram illustrating a planar shape of local bit lines LBL and global bit lines GBL according to one or more embodiments, FIG. 16 is an enlarged diagram illustrating region “B” in FIG. 15, and FIG. 17 is a cross-sectional diagram illustrating a region taken along line I-I’ in FIG. 16, a cross-sectional diagram illustrating one or more embodiments in which global bit lines GBL and peripheral circuits are further included in the cross-sectional structure in FIG. 13A. The planar shape of the first global bit lines GBL1a and the second global bit lines GBL2a illustrated in FIGS. 4A and 4B may be the same as the planar shape of the global bit lines GBL in FIGS. 15 and 16. Here, the descriptions of the elements illustrated in FIGS. 4A, 4B, 12, 13A, 13B, and 14 may not be provided, or may be directly cited, and the planar shape of the first global bit lines GBL1a and the second global bit lines GBL2a and one or more embodiments of the second structure STC2 will be described.

Referring to FIGS. 4A, 4B, 12, 13A, 13B, and 14 along with FIGS. 15 to 17, each of the first global bit lines GBL1a illustrated in FIGS. 4A and 4B may extend in the third direction D1. For example, each of the first global bit lines GBL1a may have a line shape or a bar shape extending in the third direction D1. Each of the second global bit lines GBL2a illustrated in FIGS. 4A and 4B may extend in the fourth direction D2. For example, each of the second global bit lines GBL2a may have a line shape or a bar shape extending in the fourth direction D2.

The third direction D1 may be parallel to an upper surface of the base 3. The third direction D1 may intersect the first direction X and the second direction Y.

The fourth direction D2 may be parallel to an upper surface of the base 3. The fourth direction D2 may intersect the third direction D1, the first direction X and the second direction Y.

On the plane, the first global bit lines GBL1a may intersect the second global bit lines GBL2a. For example, among the first global bit lines GBL1a and the second global bit lines GBL2a, the first global bit line GBL1a and the second global bit line GBL2a, adjacent to each other in the vertical direction Z, may intersect each other when viewed in the plan diagram as in FIGS. 15 and 16.

The first structure STC1 may further include a lower insulating structure 118 disposed on the lower structure LS. The bit line contact plugs BLC1, the bit line contact structures BLC2, the global bit lines GBL, the first lower routing interconnection portions RI1a, and the second lower routing interconnection portions RI2a illustrated in FIGS. 4A and 4B may be buried in the lower insulating structure 118.

As illustrated in FIGS. 4A and 4B, the third pad portions PD1c and the sixth pad portions PD2c may not vertically overlap the global bit lines GBL.

In example embodiments, the local bit lines LBL may be arranged in the first direction X, and three local bit lines LBL may be connected to three global bit lines GBL spaced apart from each other among the global bit lines GBL. For example, among three local bit lines LBL sequentially arranged in the first direction X as in FIG. 16, a first local bit line LBL may be a second local bit line LBL2 connected to one second global bit line GBL2a, a second local bit line LBL may be a first local bit line LBL1 connected to one first global bit line GBL1a, and a third local bit line LBL may be a second local bit line LBL2 connected to one second global bit line GBL2a.

The local bit lines LBL may include a second local bit line LBL2, a first local bit line LBL1, a second local bit line LBL2 and a first local bit line LBL1, sequentially arranged in the first direction X.

In example embodiments, as for the local bit lines LBL, four local bit lines LBL, sequentially arranged in the first direction X, may be connected to four global bit lines GBL spaced apart from each other among the global bit lines GBL.

The second structure STC2 may include a backside insulating layer 133, a substrate 121 on the backside insulating layer 133, peripheral circuits BLSA and BLSC disposed on the substrate 121, and an upper insulating structure 150 covering the peripheral circuits BLSA and BLSC on the substrate 121. The substrate 121 may be a semiconductor substrate or a semiconductor body.

The lower insulating structure 118 of the first structure STC1 and the backside insulating layer 133 of the second structure STC2 may be bonded to each other, such that a bonding region JUN may be formed between the first structure STC1 and the second structure STC2.

The second structure STC2 may include a plurality of peripheral active regions 124a, defined by device isolation regions 124s on the substrate 121.

The peripheral circuits BLSA and BLSC may include the bit line sense amplifiers BLSA and the bit line select circuits BLSC, as illustrated in FIGS. 2A and 2B.

Each of the sense amplifier transistors P1_a, P1_b, N1_a, and N1_b included in the bit line sense amplifiers BLSA illustrated in FIG. 2B may include a peripheral channel region pCHa disposed in the peripheral active region 124a between the peripheral source/drain regions pSDa and the peripheral source/drain regions pSDa, a peripheral gate electrode pGEa on the peripheral channel region pCHa, and a peripheral gate dielectric layer pGoxa between the peripheral gate electrode pGEa and the peripheral channel region pCHa. The peripheral source/drain regions pSDa of the first NMOS transistor N1_a and the second NMOS transistor N1_b illustrated in FIG. 2B may have an N-type conductivity, and the peripheral source/drain regions pSDa of the first PMOS transistor P1_a and the second PMOS transistor P1_b may have a P-type conductivity.

Each of the select transistors ST included in the bit line select circuits BLSC illustrated in FIG. 2B may include a peripheral channel region pCHb disposed in the peripheral active region 124a between the peripheral source/drain regions pSDb and the peripheral source/drain regions pSDb, a peripheral gate electrode pGEb on the peripheral channel region pCHb, and a peripheral gate dielectric layer pGoxb between the peripheral gate electrode pGEb and the peripheral channel region pCHb.

The second structure STC2 may include upper routing interconnection portions 140. Among the upper routing interconnection portions 140, an upper routing interconnection portion connected to the first lower routing interconnection portion RI1a may be included in the first routing interconnection structure RI1. Among the upper routing interconnection portions 140, an upper routing interconnection portion connected to the second lower routing interconnection portion RI2a may be included in the second routing interconnection structure RI2.

Each of the upper routing interconnection portions 140 may include a through-electrode 143 penetrating the substrate 121 and a connection interconnection 146 electrically connecting the through-electrode 143 to the select transistor ST of the bit line select circuit BLSC on the substrate 121. The through-electrode 143 may be spaced apart from the substrate 121 by an insulating spacer 138 on a side surface of the through-electrode 143.

The through-electrode 143 of the upper routing interconnection portion 140 included in the first routing interconnection structure RI1 may be connected to the third pad portion PD1c, and the through-electrode 143 of the upper routing interconnection portion 140 included in the second routing interconnection structure RI2 may be connected to the sixth pad portion PD2c.

The global bit lines GBL may be electrically connected to the bit line select circuits BLSC by the routing interconnection structures RI including the first and second routing interconnection structures RI1 and RI2.

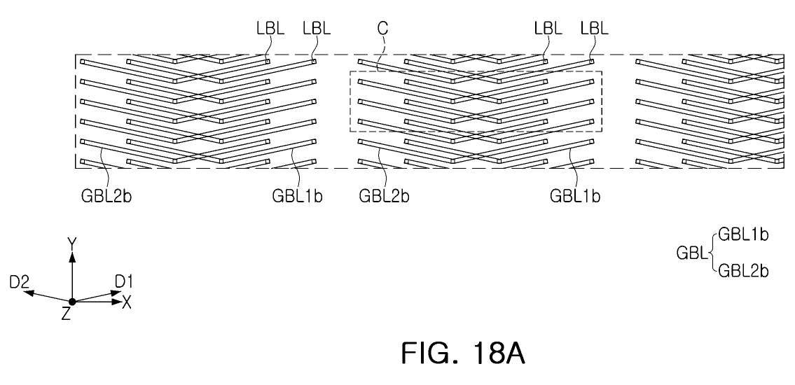

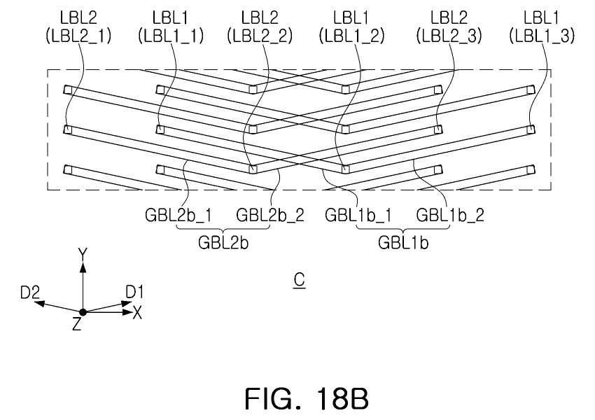

In the description below, one or more embodiments of the planar shape of the first global bit lines GBL1b and the second global bit lines GBL2b described in FIGS. 5A and 5B described above will be described referring to FIGS. 18A and 18B. FIG. 18A is a planar diagram illustrating the planar shape of local bit lines LBL and global bit lines GBL according to one or more embodiments, and FIG. 18B is an enlarged diagram illustrating region “C” in FIG. 18A. Hereinafter, elements indicating directions, for example, the third direction D1, the fourth direction D2, the vertical direction Z, the first direction X, and the second direction Y illustrated in FIGS. 15 and 16, will be directly cited without being described.

Referring to FIGS. 18A and 18B together with FIGS. 5A and 5B, each of the first global bit lines GBL1b illustrated in FIGS. 5A and 5B may include a 1-1 bit line portion GBL1b_1 extending in the fourth direction D2 and a 1-2 bit line portion GBL1b_2 extending from the 1-1 bit line portion GBL1b_1 in the third direction D1. Each of the second global bit lines GBL2b illustrated in FIGS. 5A and 5B may include a 2-1 bit line portion GBL2b_1 extending in the fourth direction D2 and a 2-2 bit line portion GBL2b_2 extending from the 2-1 bit line portion GBL2b_1 in the third direction D1.

On the plane, the first global bit lines GBL1b may intersect the second global bit lines GBL2b. For example, among the first global bit lines GBL1b and the second global bit lines GBL2b, the first global bit line GBL1b and the second global bit line GBL2b, adjacent to each other in the vertical direction Z, may intersect each other when viewed on the plane as illustrated in FIGS. 18A and 18B. For example, among the first global bit line GBL1b and the second global bit line GBL2b, the 1-1 bit line portion GBL1b_1 and the 2-2 bit line portion GBL2b_2 may intersect each other. Hereinafter, the first global bit line GBL1b and the second global bit line GBL2b, adjacent to each other in the vertical direction Z, will be described.

The three first local bit lines LBL1 connected to the first global bit line GBL1b may include a 1-1 local bit line LBL1_1, a 1-2 local bit line LBL1_2, and a 1-3 local bit line LBL1_3. The 1-1 local bit line LBL1_1 and the 1-3 local bit line LBL1_3 may be connected to both end portions of the first global bit line GBL1b, and the 1-2 local bit line LBL1_2 may be connected to a middle portion of the first global bit line GBL1b. The 1-2 local bit line LBL1_2 may be connected to the first global bit line GBL1b in the region between the 1-1 bit line portion GBL1b_1 and the 1-2 bit line portion GBL1b_2. The first global bit line GBL1b may have a bent portion between the 1-1 bit line portion GBL1b_1 and the 1-2 bit line portion GBL1b_2.

The three second local bit lines LBL2 connected to the second global bit line GBL2b may include a 2-1 local bit line LBL2_1, a 2-2 local bit line LBL2_2, and a 2-3 local bit line LBL2_3. The 2-1 local bit line LBL2_1 and the 2-3 local bit line LBL2_3 may be connected to both end portions of the second global bit line GBL2b, and the 2-2 local bit line LBL2_2 may be connected to a middle portion of the second global bit line GBL2b. The 2-2 local bit line LBL2_2 may be connected to the second global bit line GBL2b in a region between the 2-1 bit line portion GBL2b_1 and the 2-2 bit line portion GBL2b_2. The second global bit line GBL2b may have a bent portion between the 2-1 bit line portion GBL2b_1 and the 2-2 bit line portion GBL2b_2.

In example embodiments, as for the local bit lines LBL, three local bit lines LBL sequentially arranged in the first direction X, may be connected to three global bit lines GBL spaced apart from each other among the global bit lines GBL.

In example embodiments, as for the local bit lines LBL, four local bit lines LBL sequentially arranged in the first direction X may be connected to four global bit lines GBL spaced apart from each other among the global bit lines GBL.

In example embodiments, in the five local bit lines LBL sequentially arranged in the first direction X among the local bit lines LBL, the first local bit line LBL and the fifth local bit line LBL may be connected to one global bit line GBL, and the other local bit lines LBL may be connected to three different global bit lines GBL respectively.

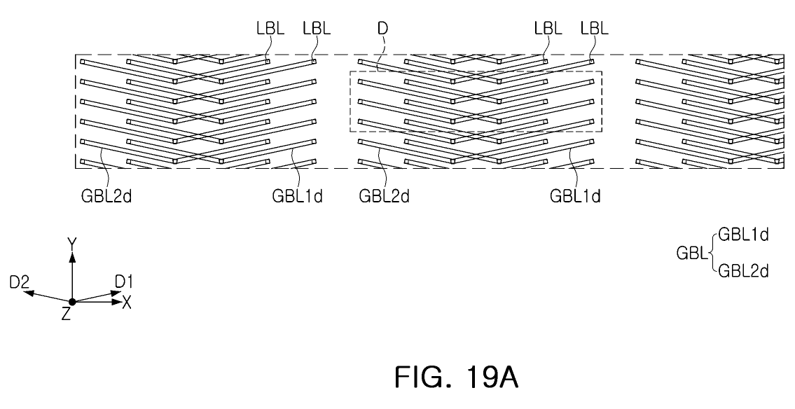

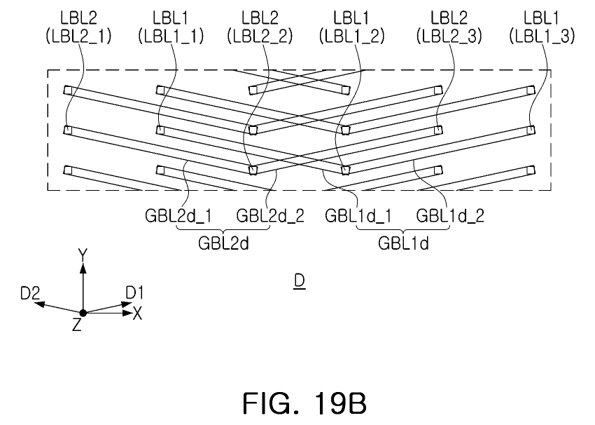

In the description below, one or more embodiments of the planar shape of the first global bit lines GBL1d and the second global bit lines GBL2d illustrated in FIGS. 7A and 7B will be described with reference to FIGS. 19A and 19B. FIG. 19A is a planar diagram illustrating a planar shape of local bit lines LBL and global bit lines GBL according to one or more embodiments, and FIG. 19B is an enlarged diagram illustrating region “D” in FIG. 19A.

Referring to FIGS. 19A and 19B together with FIGS. 7A and 7B, the 1-1 bit line portion GBL1d_1 illustrated in FIG. 7B may have substantially the same planar shape as the 1-1 bit line portion GBL1b_1 illustrated in FIGS. 18A and 18B, and the 1-2 bit line portion GBL1d_2 illustrated in FIG. 7B may have substantially the same planar shape as the 1-2 bit line portion GBL1b_2 illustrated in FIGS. 18A and 18B. The 2-1 bit line portion GBL2d_1 illustrated in FIG. 7B may have substantially the same planar shape as the 2-1 bit line portion GBL2b_1 illustrated in FIGS. 18A and 18B, and the 2-2 bit line portion GBL2d_2 illustrated in FIG. 7B may have substantially the same planar shape as the 2-2 bit line portion GBL1b_2 illustrated in FIGS. 18A and 18B.

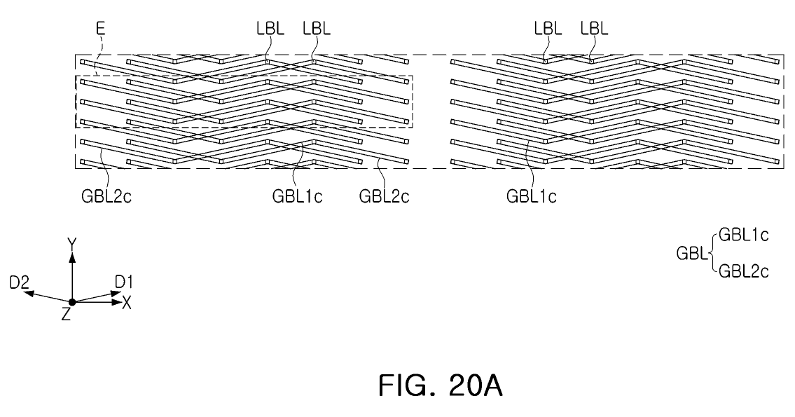

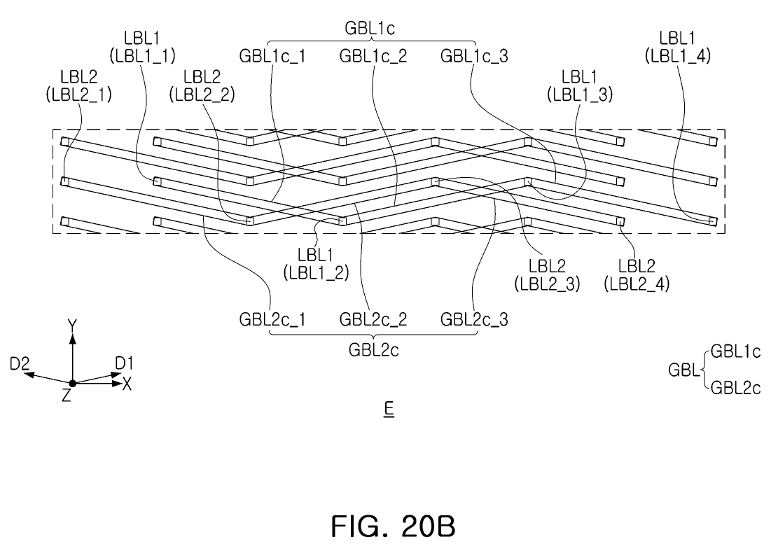

In the description below, one or more embodiments of the planar shape of the first global bit lines GBL1c and the second global bit lines GBL2c illustrated in FIGS. 6A and 6B above will be described with reference to FIGS. 20A and 20B. FIG. 20A is a planar diagram illustrating the planar shape of local bit lines LBL and global bit lines GBL according to one or more embodiments, and FIG. 20B is an enlarged diagram illustrating region “E” in FIG. 20A.

Referring to FIGS. 20A and 20B together with FIGS. 6A and 6B, each of the first global bit lines GBL1c illustrated in FIGS. 6A and 6B may include a 1-1 bit line portion GBL1c_1 and a 1-2 bit line portion GBL1c_2 having the same planar shape as the 1-1 bit line portion GBL1b_1 and the 1-2 bit line portion GBL1b_1 illustrated in FIGS. 18A and 18B, and may include a 1-3 bit line portion GBL1c_3 extending from the 1-2 bit line portion GBL1c_2 in the fourth direction D2 as in FIG. 20B. The 1-1 bit line portion GBL1c_1 and the 1-3 bit line portion GBL1c_3 may be parallel to each other.

Each of the second global bit lines GBL2c illustrated in FIGS. 6A and 6B may include a 2-1 bit line portion GBL2c_1 and a 2-2 bit line portion GBL2c_2 having the same planar shape as the 2-1 bit line portion GBL2b_1 and the 2-2 bit line portion GBL2b_1 illustrated in FIGS. 18A and 18B, and may include a 2-3 bit line portion GBL2c_3 extending from the 2-2 bit line portion GBL2c_2 in the fourth direction D2 as in FIG. 20B. The 2-1 bit line portion GBL2c_1 and the 2-3 bit line portion GBL2c_3 may be parallel to each other.

On the plane, the first global bit lines GBL1c may intersect the second global bit lines GBL2c. For example, among the first global bit lines GBL1c and the second global bit lines GBL2c, the first global bit line GBL1c and the second global bit line GBL2c, adjacent to each other in the vertical direction Z, may intersect each other when viewed in the plan diagram as in FIGS. 20A and 20B. For example, among the first global bit line GBL1c and the second global bit line GBL2c, the 1-1 bit line portion GBL1c_1 and the 2-2 bit line portion GBL2c_2 may intersect each other, and the 1-2 bit line portion GBL1c_2 and the 2-3 bit line portion GBL2c_3 may intersect each other.

The the four first local bit lines LBL1 connected to the first global bit line GBL1c may include a 1-1 local bit line LBL1_1, a 1-2 local bit line LBL1_2, a 1-3 local bit line LBL1_3, and a 1-4 local bit line LBL1_4.

The first global bit line GBL1c may have a bent portion between the 1-1 bit line portion GBL1c_1 and the 1-2 bit line portion GBL1c_2, and a bent portion between the 1-2 bit line portion GBL1c_2 and the 1-3 bit line portion GBL1c_3.

The four second local bit lines LBL2 connected to the second global bit line GBL2c may include a 2-1 local bit line LBL2_1, a 2-2 local bit line LBL2_2, a 2-3 local bit line LBL2_3, and a 2-4 local bit line LBL2_4. The second global bit line GBL2c may have a bent portion between the 2-1 bit line portion GBL2c_1 and the 2-2 bit line portion GBL2c_2, and may have a bent portion between the 2-2 bit line portion GBL2c_2 and the 2-3 bit line portion GBL2c_3.

The planar shape of the global bit lines GBL described above with reference to FIGS. 8A, 8B, 9A, 9B, 10A, 10B, 11A and 11B,may be substantially the same as the planar shape of the global bit lines GBL illustrated in FIGS. 20A and 20B.

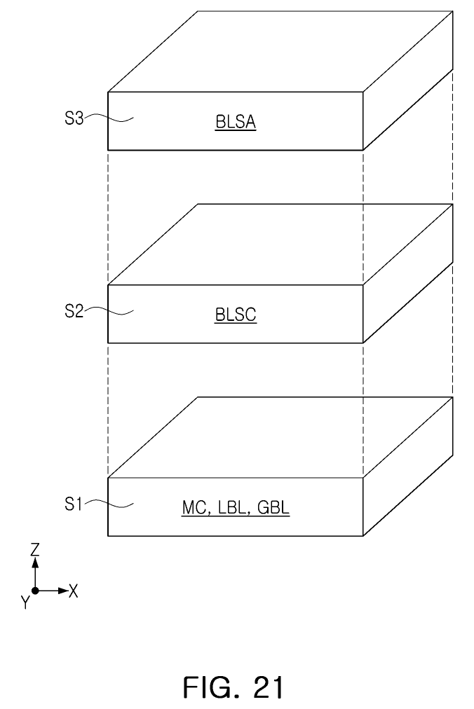

In the example embodiments described above, the bit line sense amplifiers BLSA and the bit line select circuits BLSC may be disposed at the same level as each other, but one or more embodiments thereof is not limited thereto. One or more embodiments in which the bit line sense amplifiers BLSA and the bit line select circuits BLSC are disposed at different levels will be described with reference to FIG. 21. FIG. 21 is a diagram illustrating one or more embodiments in which the bit line sense amplifiers BLSA and the bit line select circuits BLSC are disposed at different levels.

Referring to FIG. 21, a first structure S1 including the memory cells MC, the local bit lines LBL, and the global bit lines GBL described above may be disposed. A second structure S2 including the bit line select circuits BLSC described above may be disposed on the first structure S1. A third structure S3 including the bit line sense amplifiers BLSA described above may be disposed on the second structure S2. Accordingly, the bit line select circuits BLSC may be disposed at a higher level than the first structure S1, and the bit line sense amplifiers BLSA may be disposed at a higher level than the bit line select circuits BLSC.

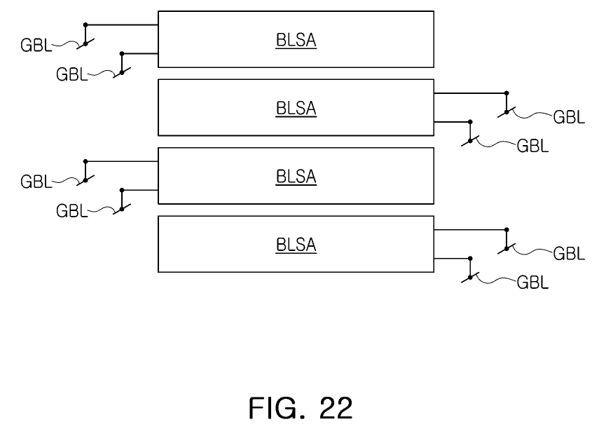

In the example embodiments described above, the bit line select circuits BLSC may not be provided. One or more embodiments in which the bit line select circuits BLSC may not be provided will be described with reference to FIG. 22. FIG. 22 is a diagram illustrating one or more embodiments in which the bit line select circuits BLSC are not provided, differently from FIG. 2A.

Referring to FIG. 22, in FIG. 2A, the bit line select circuits BLSC may not be provided, and each of the bit line sense amplifiers BLSA may be connected to a pair of global bit lines GBL.

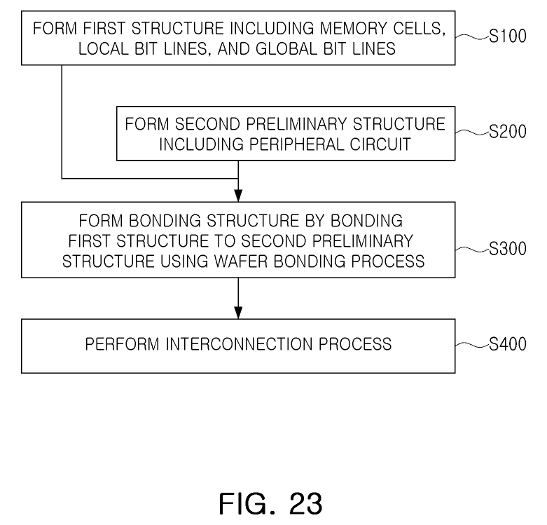

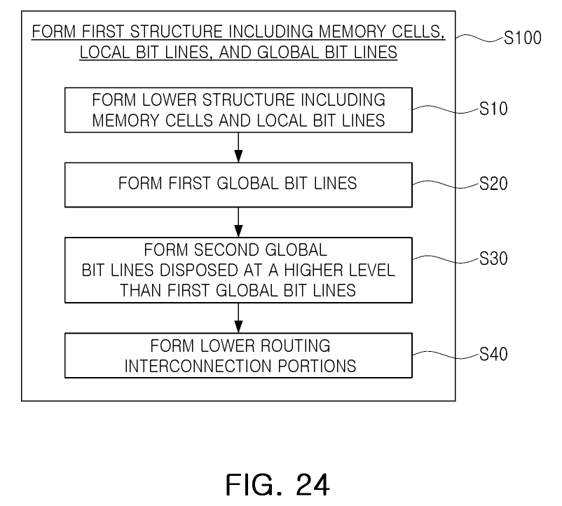

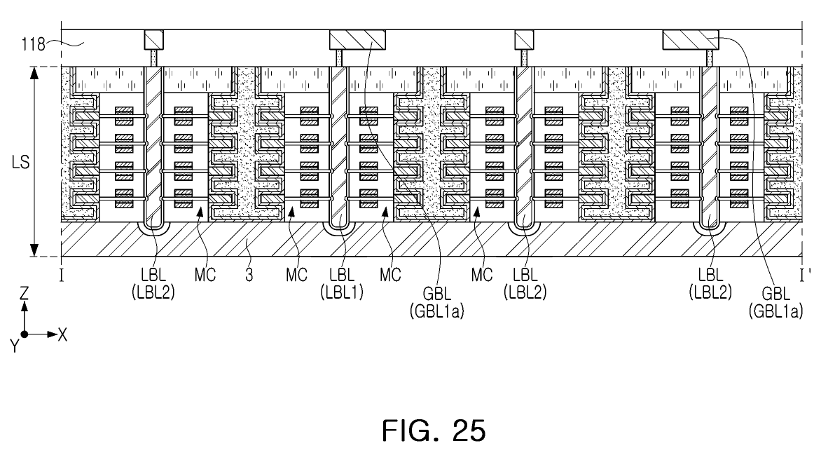

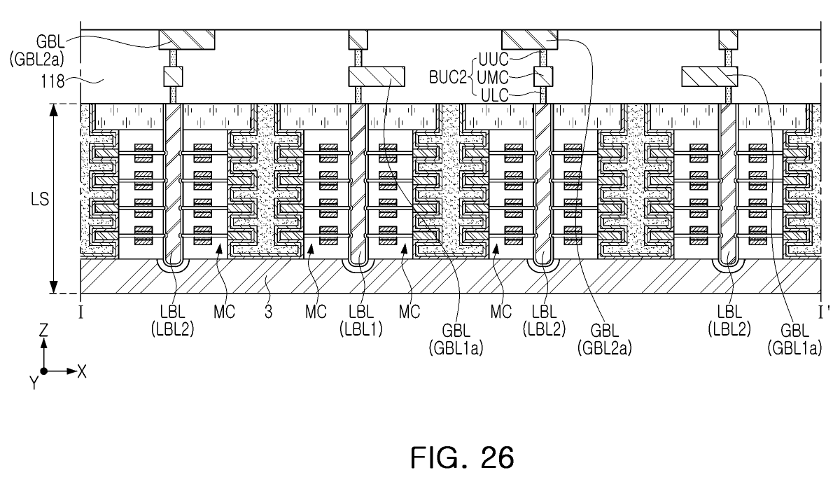

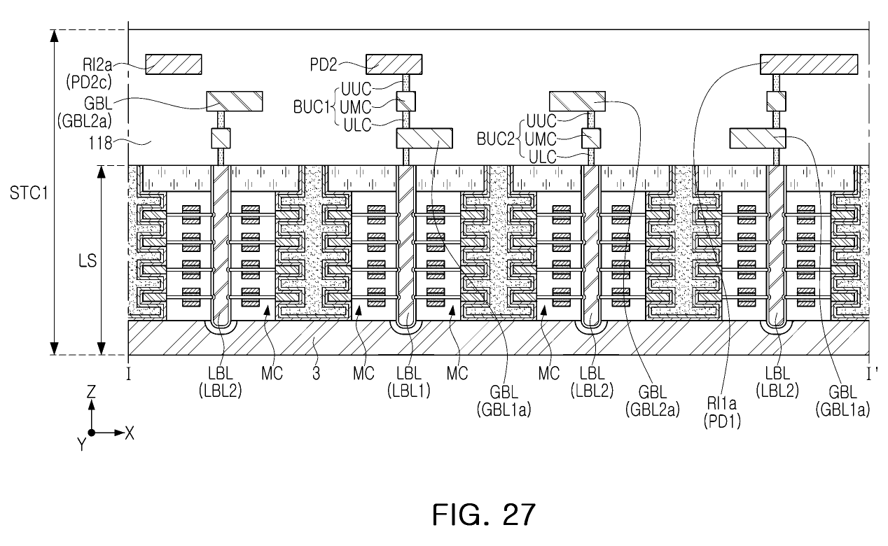

In the description below, a method of manufacturing a semiconductor device according to example embodiments will be described with reference to FIGS. 23 to 28. In FIGS. 23 to 28, FIGS. 23 and 24 are flowcharts illustrating a method of manufacturing a semiconductor device according to example embodiments, and FIGS. 25 to 28 are cross-sectional diagrams illustrating a region taken along line I-I’ in FIG. 16.

Referring to FIGS. 23, 24, and 25 to 27, a first structure STC1 including memory cells MC, local bit lines LBL, and global bit lines GBL may be formed. Forming the first structure STC1 (S100) may include forming a lower structure LS including the memory cells MC and the local bit lines LBL (S10), forming first global bit lines GBL1a (S20), forming second global bit lines GBL2a disposed at a higher level than the first global bit lines GBL1a (S30), and forming lower routing interconnection portions RI1a and RI2a (S40).

The lower structure LS may be substantially the same as illustrated in FIGS. 13A and 13B. For example, the memory cells MC may be connected to the local bit lines LBL, and each of the memory cells MC may include the cell transistor cTR and the data storage structure DS as illustrated in FIG. 13B. Accordingly, the elements illustrated in FIGS. 25 to 27 may be described as elements illustrated in FIGS. 13A and 13B.

The first global bit lines GBL1a may be formed in a lower insulating structure 118 formed on the lower structure LS. The second global bit lines GBL2a may be formed at a higher level than the first global bit lines GBL1a after the first global bit lines GBL1a are formed.

The lower routing interconnection portions RI1a and RI2a may include first lower routing interconnection portions RI1a connected to the first global bit lines GBL1a and second lower routing interconnection portions RI2a connected to the second global bit lines GBL2a.

The portions disposed at the same level in the first and second global bit lines GBL1a and GBL2a and the lower routing interconnection portions RI1a and RI2a on the lower structure LS may be formed simultaneously by the same process.

The first and second global bit lines GBL1a and GBL2a and the lower routing interconnection portions RI1a and RI2a may be formed in the lower insulating structure 118 formed on the lower structure LS.

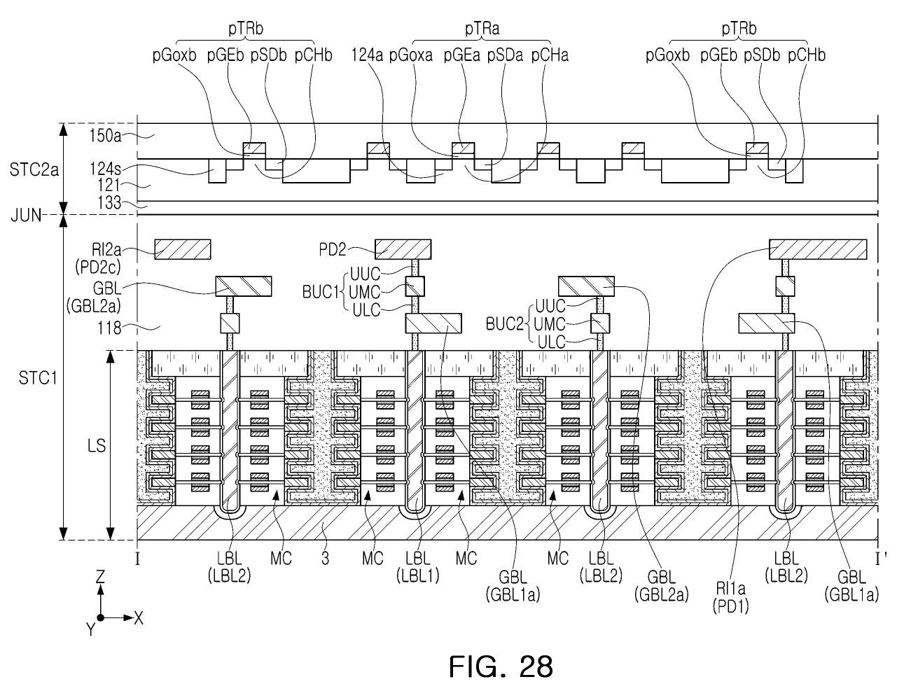

Referring to FIGS. 23 and 28, the second preliminary structure STC2a including the peripheral circuit may be formed (S200). The second preliminary structure STC2a may include peripheral transistors pTRa and pTRb formed on the substrate 121, an insulating layer 150a covering the peripheral transistors pTRa and pTRb on the substrate 121, and a backside insulating layer 133 disposed in a lower portion of the substrate 121. The peripheral transistors pTRa and pTRb may be provided to form the peripheral circuit BLSA and BLSC illustrated in FIG. 17.

Bonding structures STC1 and STC2a may be formed by bonding the first structure STC1 to the second preliminary structure STC2a using a wafer bonding process (S300). The lower insulating structure 118 of the first structure STC1 and the backside insulating layer 133 of the second preliminary structure STC2a may be bonded, thereby forming a bonding region JUN.

A interconnection process may be performed (S400). Performing the interconnection process may include forming the upper routing interconnection portions 140 illustrated in FIG. 17 and forming connection interconnections 146 for circuit connection. Accordingly, the second structure STC2 illustrated in FIG. 17 may be formed. Accordingly, the first and second structures STC1 and STC2 bonded to each other may be formed, as illustrated in FIG. 17.

According to the aforementioned example embodiments, local bit lines connected to memory cells, global bit lines connected to the local bit lines, and bit line sense amplifiers connected to the global bit lines may be provided. Each of the global bit lines may be connected to an N number of local bit lines, where N may be a natural number equal to or greater than 2. Accordingly, integration density of the semiconductor device may be increased.

Also, the global bit lines may include global bit lines disposed at different levels to reduce parasitic capacitance between the global bit lines. Accordingly, parasitic capacitance between the global bit lines may be reduced, such that performance of the semiconductor device may be improved.

Also, global bit line select circuits connected to the bit line sense amplifiers and the global bit lines may be provided. Since the global bit line select circuits may increase the number of global bit lines connected to the bit line sense amplifiers, respectively, the total number of bit line sense amplifiers required in the semiconductor device may be reduced. Accordingly, more regions for forming the bit line sense amplifiers may be ensured, such that performance of a peripheral circuit including the bit line sense amplifiers may be improved.

According to an aspect of the disclosure, a method of manufacturing a semiconductor device, may include: forming a first structure including memory cells, local bit lines, and global bit lines; forming a second preliminary structure including a peripheral circuit; forming a bonding structure by bonding the first structure to the second preliminary structure using a wafer bonding process; and performing an interconnection process.

The forming the first structure may include: forming a lower structure including the memory cells and the local bit lines; forming first global bit lines among the global bit lines; forming second global bit lines among the global bit lines, the second global bit lines being disposed at a higher level than the first global bit lines in a vertical direction of the semiconductor device; and forming lower routing interconnection portions.

The performing the interconnection process may include forming upper routing interconnection portions.

The lower routing interconnection portions may be formed on a lower insulating structure formed on the lower structure.

While the example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
memory cells disposed three-dimensionally in a vertical direction, a first direction, and a second direction perpendicular to each other;
local bit lines disposed at a same level in the vertical direction and connected to the memory cells; and
global bit lines disposed at a higher level in the vertical direction than the local bit lines and connected to the local bit lines, wherein the global bit lines comprise:
first global bit lines connected to N first local bit lines among the local bit lines, wherein N is a natural number equal to or greater than 2; and
second global bit lines connected to N second local bit lines among the local bit lines,
wherein each of the memory cells comprises:
a cell transistor comprising a cell gate electrode extending in the second direction; and
a data storage structure,
wherein each of the first global bit lines comprises a first bit line portion,
wherein each of the second global bit lines comprises a second bit line portion disposed at a higher level in the vertical direction than the first bit line portions of the first global bit lines, and
wherein three local bit lines, sequentially disposed in the first direction among the local bit lines, are respectively connected to three global bit lines that are spaced apart among the global bit lines.

2. The semiconductor device of claim 1, further comprising:
bit line contact plugs disposed between the first global bit lines and the first local bit lines, and connecting the first global bit lines to the first local bit lines; and
bit line contact structures disposed between the second global bit lines and the second local bit lines, and connecting the second global bit lines to the second local bit lines.

3. The semiconductor device of claim 2, wherein each of the bit line contact structures comprises:
a lower contact plug disposed at a same level in the vertical direction as the bit line contact plugs and connected to a corresponding second local bit line among the second local bit lines;
an intermediate contact plug disposed at a same level in the vertical direction as the first global bit lines and connected to the lower contact plug; and
an upper contact plug disposed between a corresponding second global bit line among the second global bit lines and the intermediate contact plug.

4. The semiconductor device of claim 1, further comprising:
bit line sense amplifiers disposed at a higher level in the vertical direction than the global bit lines; and
routing interconnection structures configured to connect the global bit lines to the bit line sense amplifiers.

5. The semiconductor device of claim 4, wherein the routing interconnection structures comprise first routing interconnection structures connected to the first global bit lines and second routing interconnection structures connected to the second global bit lines,
wherein each of the first routing interconnection structures comprises:
a first plug pattern connected to a corresponding first global bit line among the first global bit lines; and
a first pad pattern disposed at a higher level in the vertical direction than the global bit lines and connected to the first plug pattern, and
wherein each of the second routing interconnection structures comprises:
a second plug pattern connected to a corresponding second global bit line among the second global bit lines; and
a second pad pattern disposed at a same level in the vertical direction as the first pad patterns and connected to the second plug pattern.

6. The semiconductor device of claim 5, wherein each of the first plug patterns comprises:
a lower plug pattern connected to the corresponding first global bit line among the first global bit lines;
an intermediate plug pattern disposed on the lower plug pattern and disposed at a same level in the vertical direction as the second global bit lines; and
an upper plug pattern between the intermediate plug pattern and the first pad pattern.

7. The semiconductor device of claim 5, wherein each of the first pad patterns comprises:
a first pad portion vertically overlapping and connected to a corresponding first plug pattern among the first plug patterns;
a second pad portion extending from the first pad portion; and
a third pad portion extending from the second pad portion,
wherein, in each of the first pad patterns, a width of the third pad portion is greater than a width of the second pad portion, and
wherein the third pad portions do not vertically overlap the first global bit lines.

8. The semiconductor device of claim 4, further comprising:
global bit line select circuits connected to the bit line sense amplifiers.

9. The semiconductor device of claim 8, wherein the bit line sense amplifiers comprise sense amplifier transistors, and
wherein the global bit line select circuits comprise select transistors disposed at a same level in the vertical direction as the sense amplifier transistors.

10. The semiconductor device of claim 9, wherein the routing interconnection structures are connected to the select transistors, and
wherein the global bit lines are configured to be connected to the bit line sense amplifiers through the routing interconnection structures based on operation of the select transistors.

11. A semiconductor device, comprising:
memory cells disposed three-dimensionally in a vertical direction, a first direction, and a second direction perpendicular to each other;
local bit lines connected to the memory cells and disposed at a same level in the vertical direction;
global bit lines disposed at a higher level in the vertical direction than the local bit lines and connected to the local bit lines;
bit line sense amplifiers disposed at a higher level in the vertical direction than the global bit lines; and
global bit line select circuits connected to the bit line sense amplifiers and the global bit lines,
wherein each of the global bit lines is connected to N local bit lines among the local bit lines, wherein N is a natural number equal to or greater than 2,
wherein a first global bit line among the global bit lines comprises a first bit line portion,
wherein a second global bit line among the global bit lines comprises a second bit line portion disposed at a higher level in the vertical direction than the first bit line portion,
wherein the global bit line select circuits comprise a first global bit line select circuit connected to a first bit line sense amplifier among the bit line sense amplifiers, and
wherein the global bit lines comprise M global bit lines connected to the first global bit line select circuit, wherein M is a natural number equal to or greater than 4.

12. The semiconductor device of claim 11, wherein the first global bit line select circuit comprises:
a first select circuit connected to the first global bit line and the second global bit line; and
a second select circuit connected to a third global bit line and a fourth global bit line among the global bit lines.

13. The semiconductor device of claim 12, wherein the first select circuit comprises:
a first select transistor connected to the first global bit line; and
a second select transistor connected to the second global bit line, and
wherein the second select circuit comprises:
a third select transistor connected to the third global bit line; and
a fourth select transistor connected to the fourth global bit line.

14. The semiconductor device of claim 13, wherein the first select circuit is disposed on a first side of the first bit line sense amplifier, and
wherein the second select circuit is disposed on a second side of the first bit line sense amplifier, opposing the first side of the first bit line sense amplifier.

15. The semiconductor device of claim 13, wherein the first select transistor of the first select circuit and the third select transistor of the second select circuit are disposed on a first side of the first bit line sense amplifier, and
wherein the second select transistor of the first select circuit and the fourth select transistor of the second select circuit are disposed on a second side of the first bit line sense amplifier, opposing the first side of the first bit line sense amplifier.

16. The semiconductor device of claim 13, wherein the first global bit line and the third global bit line are disposed at a same level in the vertical direction, and
wherein the second global bit line and the fourth global bit line are at a different level in the vertical direction from the first global bit line and the third global bit line.

17. A semiconductor device, comprising:
a first structure; and
a second structure disposed on the first structure and bonded to the first structure,
wherein the first structure comprises:
memory cells disposed three-dimensionally in a vertical direction, a first direction, and a second direction perpendicular to each other;
local bit lines connected to the memory cells and disposed at a same level in the vertical direction; and
global bit lines disposed at a higher level in the vertical direction than the local bit lines and connected to the local bit lines,
wherein the global bit lines comprise:
first global bit lines connected to N first local bit lines among the local bit lines, wherein an N is a natural number equal to or greater than 2; and
second global bit lines connected to N second local bit lines among the local bit lines,
wherein each of the memory cells comprises:
a cell transistor comprising a cell gate electrode extending in the second direction; and
a data storage structure,
wherein each of the first global bit lines comprises a first bit line portion,
wherein each of the second global bit lines comprises a first bit line portion disposed at a higher level in the vertical direction than the first bit line portions of the first global bit lines, and
wherein three local bit lines, disposed in the first direction among the local bit lines, are respectively connected to three global bit lines that are spaced apart among the global bit lines.

18. The semiconductor device of claim 17, wherein, among the first global bit lines and the second global bit lines, in a first global bit line and a second global bit line adjacent in the vertical direction, the first bit line portion of the first global bit line extends in a third direction intersecting the first direction and the second direction, and the first bit line portion of the second global bit line extends in a fourth direction intersecting the first direction, the second direction and the third direction, and
wherein, in a plan view, the first bit line portion of the first global bit line intersects the first bit line portion of the second global bit line.

19. The semiconductor device of claim 17, wherein, among the first global bit lines and the second global bit lines, in a first global bit line and a second global bit line adjacent in the vertical direction, the first bit line portion of the first global bit line extends in a third direction intersecting the first direction and the second direction, and the first bit line portion of the second global bit line extends in a fourth direction intersecting the first direction, the second direction and the third direction,
wherein each of the first global bit lines further comprises a second bit line portion extending from the first bit line portion of the first global bit line in the fourth direction, and
wherein each of the second global bit lines further comprises a second bit line portion extending from the first bit line portion of the second global bit line in the third direction.

20. The semiconductor device of claim 19, wherein the first bit line portion of the first global bit line and the second bit line portion of the first global bit line are disposed at different levels in the vertical direction, and
wherein the first bit line portion of the second global bit line and the second bit line portion of the second global bit line are disposed at different levels in the vertical direction.
